(19) United States
(12) Patent Application Publication
(10) Pub. No.: US 2026/0198066 A1
(43) Pub. Date: Jul. 9, 2026

(54) METAL GATE ETCH-BACK IN SEMICONDUCTOR DEVICES

(71) Applicant: Taiwan Semiconductor Manufacturing Company, Ltd., Hsin-Chu (TW)

(72) Inventors: Yuan-Bang Lee, Tongxiao Town (TW); Bing-Hung Chen, San-Xia Town (TW); Chun-Yu Liu, New Taipei City (TW); Hsien-Chung Huang, Hsinchu (TW); Chu-Hsuan Sha, Hsinchu City (TW); Shun-Wu Lin, Hsinchu (TW); Ying-Liang Chuang, Zhubei City (TW); I-Hung Li, New Taipei City (TW)

(21) Appl. No.: 19/176,555

(22) Filed: Apr. 11, 2025

Related U.S. Application Data
(60) Provisional application No. 63/742,600, filed on Jan. 7, 2025.

(51) Int. Cl. H10D 84/01; H01L 21/02; H01L 21/28; H01L 21/3213

(52) U.S. Cl. CPC H10D 84/014; H10D 64/01304; H10D 84/0144; H10P 50/267; H10P 50/269; H10P 70/27

(57) ABSTRACT

A method includes forming top semiconductor channels for a top device over bottom semiconductor channels for a bottom device; forming a high-k gate dielectric layer wrapping around each of the top and the bottom semiconductor channels; forming a first gate metal over the high-k gate dielectric layer; etching back the first gate metal to expose top portions of the high-k gate dielectric layer while bottom portions of the high-k gate dielectric layer remain, wherein the etching back includes dry etching to etch the first gate metal and to generate a co-polymer byproduct that covers the exposed top portions of the high-k gate dielectric layer; and performing a post-cleaning process to remove the co-polymer byproduct, the post-cleaning process comprising a first wet cleaning to remove silicon oxide components of the co-polymer byproduct and a second wet cleaning to remove metal oxide components of the co-polymer byproduct.

### PRIORITY DATA

This application claims the benefit of U.S. Provisional Application No. 63/742,600, filed Jan. 7, 2025, which is hereby incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Metal gates may be etched-back in order to deposit various other layers for gate tuning and improving device performance. For example, a metal gate may include work function metals that are etched back, then a fill metal is deposited over the etched-back work function metals. For another example, a first gate metal may be deposited over a stacked semiconductor device having a top device over a bottom device (e.g., a complementary field-effect transistor (CFET) device). Then, a top portion of the first gate metal is etched-back and removed from the top device, thereby forming the gate for the bottom device. Then, a second gate metal is deposited over the first gate metal, thereby forming the gate for the top device.

Traditional metal etch-back processes have low selectivity, which may lead to gate dielectric loss (e.g., when gate metal is etched deeper), making them unsuitable for removing gate metal in stacked devices (e.g., CFET devices). Further, traditional etch-back processes have weaker plasma penetration, making it more difficult to etch devices that require greater etch-back depth.

Therefore, while existing gate etch-back process are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIGS. 1A-1B illustrate a flow chart of a method to form a stacked semiconductor device (e.g., a CFET device), in portion or in entirety, according to an embodiment of the present disclosure.

FIGS. 2-9 illustrate cross-sectional views of a stacked semiconductor device (e.g., a CFET device), at intermediate stages of fabrication and processed in accordance with the method of FIGS. 1A-1B, according to an embodiment of the present disclosure.

FIG. 10 illustrates a flow chart of a method for metal gate etch-back in a stacked semiconductor device (e.g., a CFET device), in portion or in entirety, according to an embodiment of the present disclosure.

FIG. 11 illustrates a top view of a semiconductor workpiece after the method of FIGS. 1A-1B and with lines A-A′, B-B′, and C-C′ cut across the workpiece.

FIGS. 12A, 13A, 14A, and 15A illustrate cross-sectional views of stacked semiconductor device cut along the line A-A′ in FIG. 11 at intermediate stages of fabrication and processed in accordance with the method of FIG. 10, according to an embodiment of the present disclosure.

FIGS. 12B, 13B, 14B, and 15B illustrate cross-sectional views of stacked semiconductor device cut along the line B-B′ in FIG. 11 at intermediate stages of fabrication and processed in accordance with the method of FIG. 10, according to an embodiment of the present disclosure.

FIGS. 12C, 13C, 14C, and 15C illustrate cross-sectional views of stacked semiconductor device cut along the line C-C′ in FIG. 11 at intermediate stages of fabrication and processed in accordance with the method of FIG. 10, according to an embodiment of the present disclosure.

FIG. 16 illustrates a flow chart of a method for metal gate-etch back in a stacked semiconductor device (e.g., a CFET device), in portion or in entirety, according to another embodiment of the present disclosure.

FIGS. 17A, 18A, 19A, 20A, and 21A illustrate cross-sectional views of stacked semiconductor device cut along the line A-A′ in FIG. 11 at intermediate stages of fabrication and processed in accordance with the method of FIG. 16, according to an embodiment of the present disclosure.

FIGS. 17B, 18B, 19B, 20B, and 21B illustrate cross-sectional views of stacked semiconductor device cut along the line B-B′ in FIG. 11 at intermediate stages of fabrication and processed in accordance with the method of FIG. 16, according to an embodiment of the present disclosure.

FIGS. 17C, 18C, 19C, 20C, and 21C illustrate cross-sectional views of stacked semiconductor device cut along the line A-A′ in FIG. 11 at intermediate stages of fabrication and processed in accordance with the method of FIG. 16, according to an embodiment of the present disclosure.

FIG. 22 illustrates a manufacturing flow including an etch-back and a post-clean process, according to an embodiment of the present disclosure.

FIGS. 23-24 illustrate details of a post-clean process, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” or the like, may be understood to be within +/−10% between the compared features. Further, disclosed dimensions of the different features can implicitly disclose dimension ratios between the different features.

The present disclosure addresses various issues present in metal gate etch-back processes. Metal gate etch-back has typically been performed using Cl₂/BCl₃ plasma etch and employing polymer containing B to protect the metal seams (or metal voids). However, BCl₃ will etch exposed high-k gate dielectrics, and the Cl₂/BCl₃ plasma has higher energy and a weaker penetration. Therefore, the metal gate etch-back cannot achieve a good selectivity for underlying material high-k and metal seams. The high-k gate dielectric loss makes these processes unsuitable for metal gate etch-back in CFET or other stacked transistor devices.

For this and other reasons, the present disclosure provides a highly selective metal gate etch-back process to prevent damaging the exposed high-k gate dielectric layers. The etch-back process includes generating removable polymer by-products to plug metal seams and to protect the surface of the high-k gate dielectric layers. The etch-back process further includes (or is followed up with) a post-clean process that selectively removes the polymer by-products without damaging the high-k gate dielectric layers. The etch-back process may include performing dry etch using radicals formed from Cl₂/SiCl₄/O₂ or Clₓ/SiₓCl_{y}/Oₓ/COₓ. The dry etch generates a heavy and removable oxide polymer (e.g., SiOₓ) to plug metal seams in the metal gate and cover exposed surfaces of the high-k gate dielectric. This results in the metal etch producing a high selectivity for high-k and metal seam. The removable oxide polymer is a by-product from the etching and may include a SiₓTi_{y}O_{z} co-polymer (e.g., when the metal gate includes titanium). After the etch-back, a wet clean process is performed. The wet clean may include applying NH₄OH to remove the SiO components in the by-product and applying HCl to remove the TiO components in the by-product, ensuring precise and complete polymer removal without damaging high-k materials or metal seams. This etch-back process is suitable in forming gates of stacked devices (e.g. CFET) because the etch-back is selective to the gate metal and does not damage the exposed gate-dielectric or other gate layers.

The present disclosure is described in relation to forming stacked semiconductor devices such as CFET semiconductor devices having vertically stacked NFET and PFET devices. However, the present disclosure applies to any combination of stacked semiconductor devices, including an NFET stacked above a PFET, a PFET stacked above an NFET, an NFET stacked above an NFET, and a PFET stacked above a PFET.

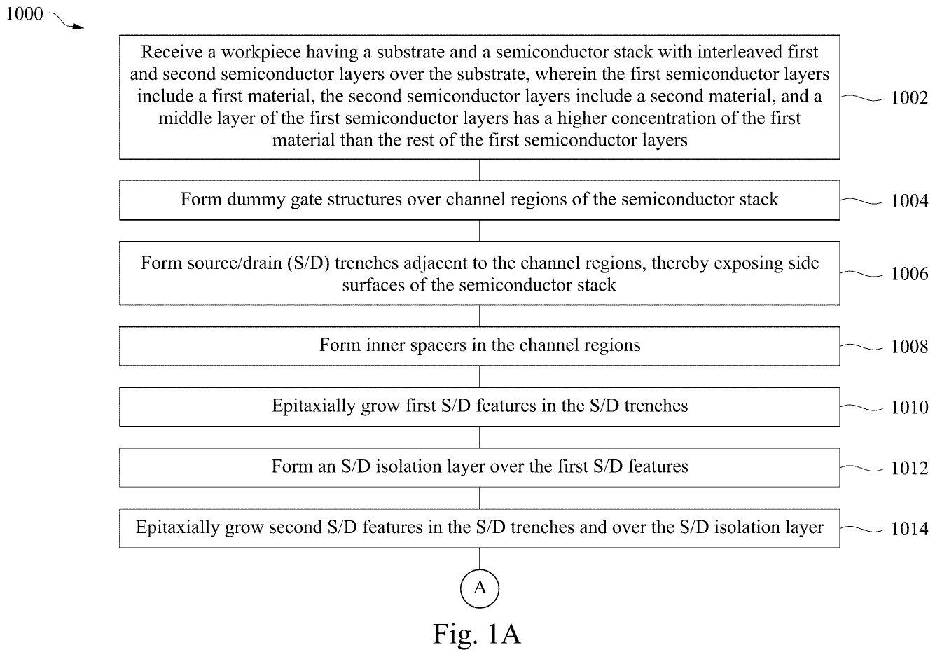

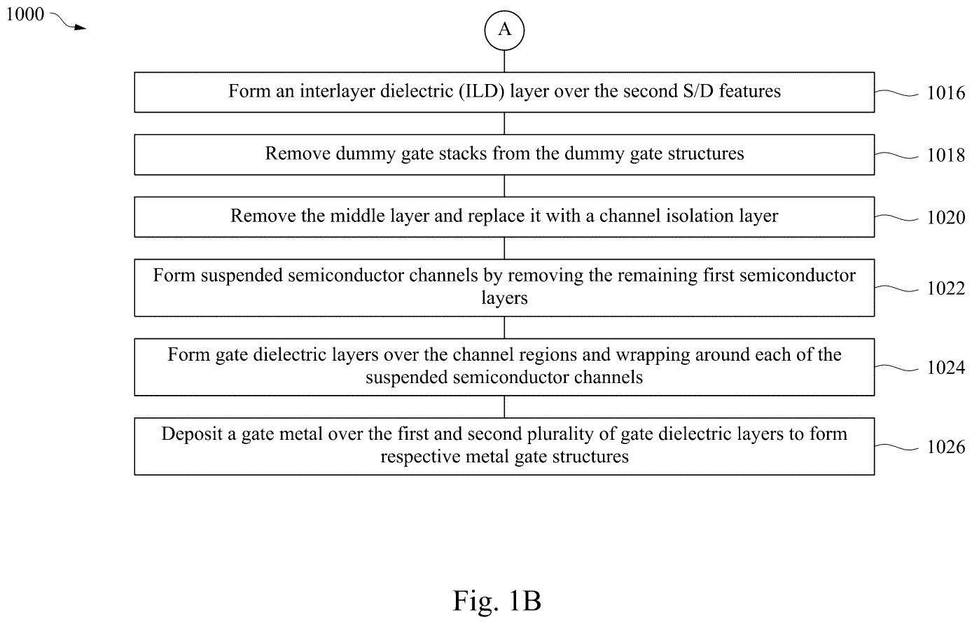

FIGS. 1A-1B illustrate a flow chart of a method 1000 to form a stacked semiconductor device (e.g., a CFET device 100), in portion or in entirety, according to an embodiment of the present disclosure. The device 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

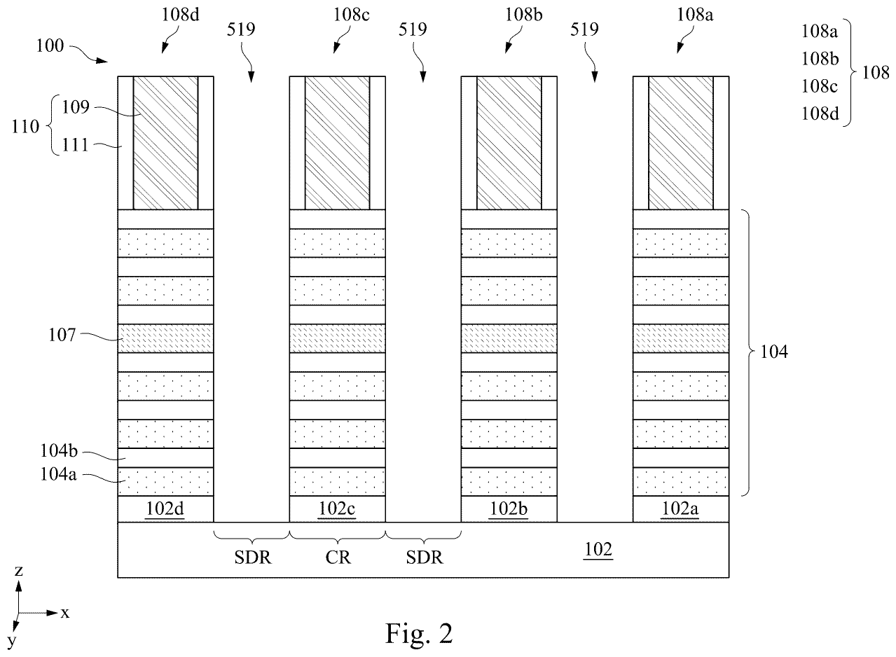

FIGS. 2-9 illustrate cross-sectional views of a stacked semiconductor device (e.g., a CFET device 100), at intermediate stages of fabrication and processed in accordance with the method 1000 of FIGS. 1A-1B, according to an embodiment of the present disclosure. The method 1000 is described below with reference to FIGS. 2-9.

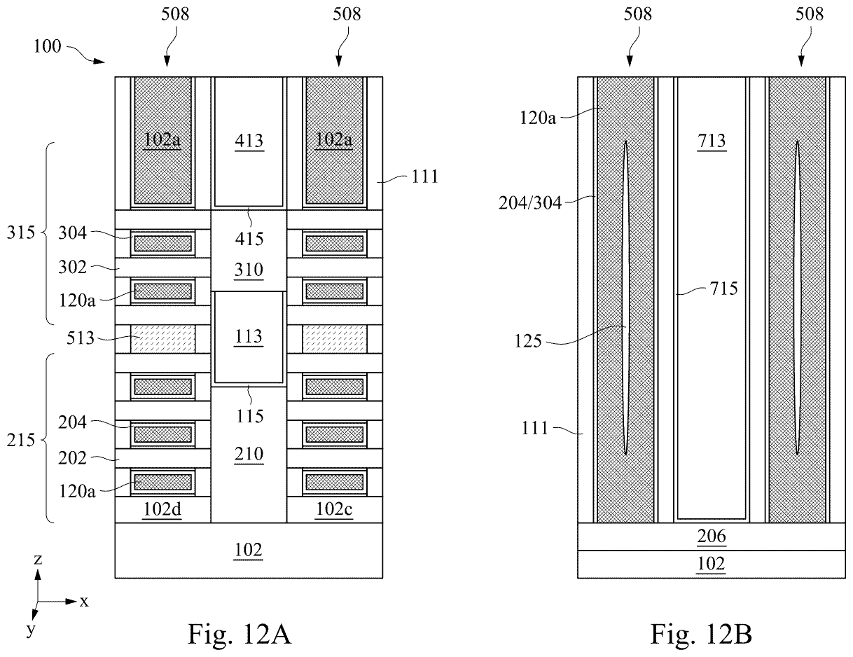

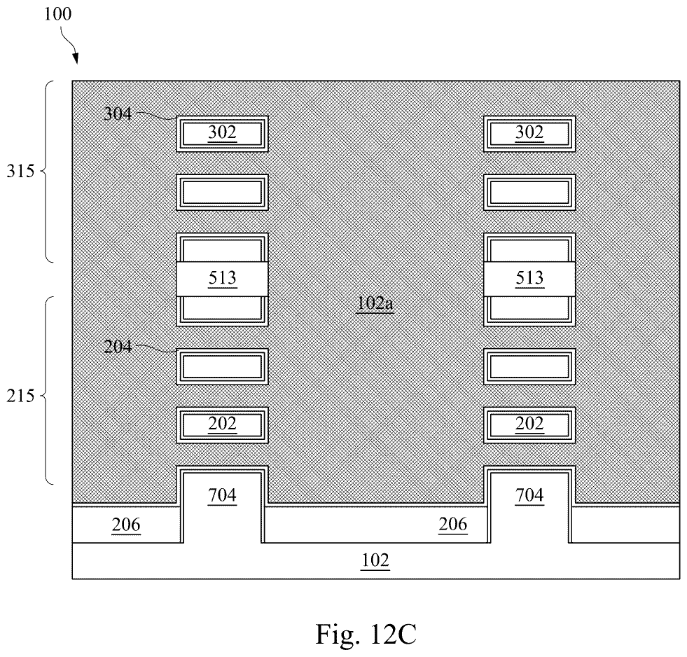

Referring to FIG. 2, the method 1000 at operation 1002 receives or is provided with a workpiece having a substrate 102 and a semiconductor stack 104 with interleaved first and second semiconductor layers 104a and 104b over the substrate 102. The substrate 102 may be a silicon (Si) substrate, or a substrate having other semiconductor materials such as germanium (Ge), silicon carbide (SiC), silicon germanium (SiGe), or diamond. The semiconductor stack 104 may also be referred to as active regions (or fin active regions that protrude from the substrate 102 and extend lengthwise along the x direction. Although not shown, additional semiconductor stacks 104 may be formed in parallel along the y direction, and the semiconductor stacks 104 are separated from each other by an isolation structure such as a shallow trench isolation (STI) structure (e.g., see STI structure 206 in FIGS. 12B and 12C).

The first semiconductor layers 104a have a different material composition than the second semiconductor layers 104b to achieve etch selectivity. For example, each of the first semiconductor layers 104a is made of silicon germanium and each of the second semiconductor layers 104b is made of silicon. Note that the first semiconductor layers 104a include a middle layer 107 that has a different concentration makeup than the rest of the first semiconductor layers 104a. For example, the middle layer 107 is made of silicon germanium but has a greater concentration of germanium than the rest of the first semiconductor layers 104a. In furtherance of the example, the first semiconductor layers 104a are SiGe layers with germanium concentration ranging between 20% and 25% (atomic percentage), and the middle layer 107 is a silicon germanium layer with germanium concentration greater than 30% (atomic percentage), such as ranging between 40% and 60%. This allows for selective etching of the middle layer 107 in a later process step, where the middle layer 107 is replaced with a channel isolation layer to separate a top device from a bottom device of the CFET device 100. Note that the middle layer 107 does not necessarily have to be in the exact middle to separate a top device from a bottom device. This layer may be closer to the top of the stack or closer to the bottom of the stack, and as such, it is possible that the bottom device will have more or less semiconductor channels than the top device. In an embodiment shown in FIG. 2, the first semiconductor layers 104a include a first material (i.e., germanium), the second semiconductor layers 104b include a second material (i.e., silicon), and a middle layer 107 of the first semiconductor layers 104a has a higher concentration of the first material (i.e., germanium) than the rest of the first semiconductor layers 104a. The second semiconductor layers 104b may be of a same material composition as the substrate 102.

Still referring to FIG. 2, the method 1000 at operation 1004 forms dummy gate structures 110 over channel regions CR of the semiconductor stack 104. The channel regions CR include channel regions 102a-102d that are part of the substrate 102. The dummy gate structures 110 define various CFET gate regions 108. For example, the CFET gate regions may include CFET gate regions 108a, 108b, 108c, and 108d. Each of the dummy gate structures 110 includes a dummy gate stack 109 and gate spacers 111 over sidewalls of the dummy gate stack 109. The dummy gate stack 109 may be made of polysilicon and the gate spacers 111 may be made of silicon oxide, silicon nitride, silicon oxycarbide, silicon oxycarbonitride, silicon carbonitride, metal nitride, or a suitable dielectric material.

Still referring to FIG. 2, the method 1000 at operation 1006 forms source/drain (S/D) trenches 519 in S/D regions SDR adjacent to the channel regions CR, thereby exposing side surfaces of the semiconductor stack 104. The S/D trenches 519 may be formed by a dry etching process, a wet etching process, other suitable etching process, or combinations thereof. In some embodiments, the etching process is a multi-step etch process. For example, the etching process may include alternative etchants to separately and alternately remove first semiconductor layers 104a and semiconductor layers 104b. In some embodiments, parameters of the etching process are configured to selectively etch the semiconductor stack 104 with minimal (to no) etching of dummy gate structures 110 (i.e., dummy gate stacks 109 and gate spacers 111). In some embodiments, a lithography process is performed to form a patterned mask layer that covers dummy gate structures 110 and/or portions of an isolation structure between semiconductor stacks 104, and the etching process uses the patterned mask layer as an etch mask when forming the S/D trenches 519. Note that the etching process may also etch slightly into the substrate 102. That is, when forming the S/D trenches 519, the substrate 102 may be recessed to form protruding portions that define the channel regions 102a, 102b, 102c, and 102d.

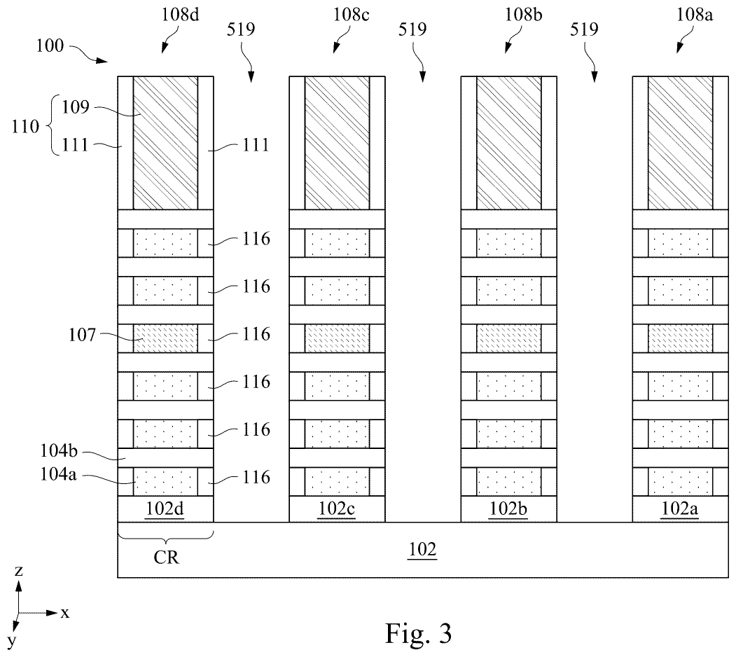

Now referring to FIG. 3, the method 1000 at operation 1008 forms inner spacers 116 in the channel regions CR along sidewalls of the first semiconductor layers 104a by any suitable process. For example, a side etch process is first performed to selectively etch sidewalls of the first semiconductor layers 104a without etching (or substantially etching) the second semiconductor layers 104b. In other words, the side etch process is configured to laterally etch (e.g., along the x direction) first semiconductor layers 104a, thereby reducing a length of first semiconductor layers 104a along the x direction. The side etch process is a dry etching process, a wet etching process, other suitable etching process, or combinations thereof. After the side etch process is performed, air gaps are formed under each of the second semiconductor layers 104b. Then, as shown in FIG. 3, inner spacers 116 are formed in each of the air gaps. The inner spacers 116 are disposed directly below the gate spacers 111, and they may be substantially vertically aligned with the gate spacers 111 along the z direction.

The inner spacers 116 may be formed by a spacer deposition process and a spacer etching process. For example, a spacer deposition process is performed to form a spacer layer over the dummy gate structures 110 and over features defining the S/D trenches 519 (e.g., semiconductor layers 104a, semiconductor layers 104b, and substrate 102). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 519. The spacer deposition process is configured to ensure that the spacer layer fills the air gaps between semiconductor layers 104b and between semiconductor layers 104b and the respective channel regions 102a-102d under gate spacers 111. A spacer etching process is then performed that selectively etches the spacer layer to form inner spacers 116 as depicted in FIG. 3 with minimal (to no) etching of semiconductor layers 104b, dummy gate stacks 109, and gate spacers 111. In the disclosed embodiment, the spacer etching process includes an anisotropic etching, such as plasma etch. The spacer layer (and thus inner spacers 116) includes a material that is different than a material of semiconductor layers 104b and a material of gate spacers 111 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride).

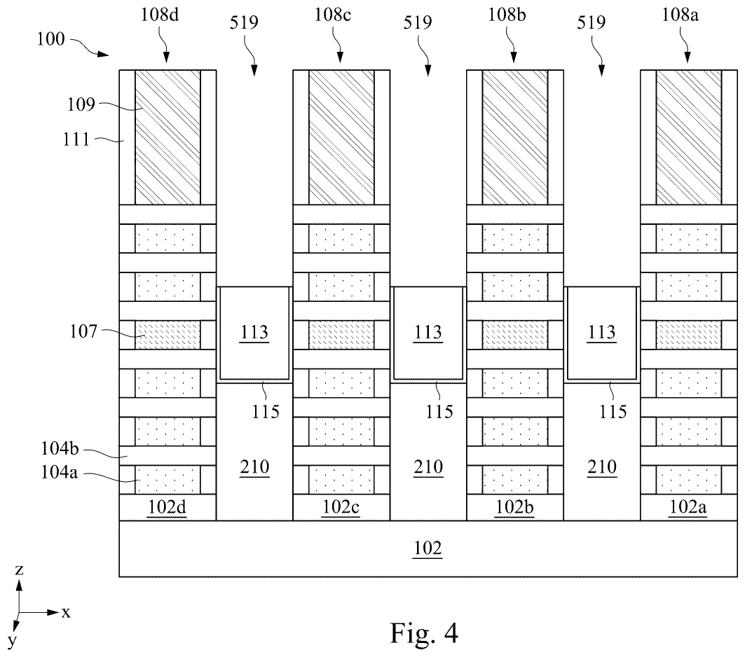

Now referring to FIG. 4, the method 1000 at operation 1010 epitaxially grows first S/D features 210 in the S/D trenches 519 for bottom transistor devices of the CFET device 100. The bottom transistor devices may be NFET transistor devices or PFET transistor devices. As such, the first source/drain features 210 may include n-type source/drain features that correspond with n-type transistor regions or p-type source/drain features that correspond with p-type transistor regions. The first source/drain features 210 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 102 and/or semiconductor stacks 104 (in particular, semiconductor layers 104b). Epitaxial source/drain features are doped with n-type dopants and/or p-type dopants. In some embodiments, for the n-type CFET transistors, first epitaxial source/drain features 210 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In some embodiments, for the p-type CFET transistors, first epitaxial source/drain features 210 include silicon germanium or germanium and can be doped with boron, other p-type dopant, or combinations thereof (for example, forming Si:Ge:B epitaxial source/drain features). In the embodiment shown, the first S/D features 210 are p-type S/D features for PFET devices.

Still referring to FIG. 4, the first S/D features 210 only partially fill the S/D trenches 519. Specifically, they are grown (or grown and recessed) to a height below the middle layer 107 in the z direction. That is, the first S/D features 210 are in direct contact with semiconductor layers 104b for bottom transistor devices under the middle layer 107, but not the semiconductor layers 104b above the middle layer 107. Note that in some embodiments, like as shown, the first S/D features 210 need not be in direct contact with all the semiconductor layers 104b under the middle layer 107.

Still referring to FIG. 4, the method 1000 at operation 1012 forms an S/D isolation layer 113 over the first S/D features 210. This may be done by first conformably depositing a dielectric liner such as an etch stop layer 115 by CVD, ALD or other suitable processes, then depositing the S/D isolation layer 113 over the etch stop layer 115. An etch process may follow to recess top surfaces of the S/D isolation layer 113 and etch stop layer 115. In some embodiments, the operation 1012 includes depositing the etch stop layer 115 and the S/D isolation layer 113, performing a chemical mechanical polishing (CMP), and etching to recess the deposited materials. In some embodiments, the operation 1012 may apply a selective deposition. The etch stop layer 115 may include silicon nitride and the S/D isolation layer 113 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof.

The S/D isolation layer 113 only partially fill the S/D trenches 519 since second S/D features 310 are to be formed over the S/D isolation layer 113. However, although only partially filled, the S/D isolation layer 113 should be thick enough to isolate the first S/D features 210 from the later formed second S/D features 310. As such, in some embodiments, like as shown, the S/D isolation layer 113 (or etch stop layer 115) may be in direct contact with sidewalls of the second semiconductor layers 104b, thereby isolating them from contacting the first or second S/D features 210 and 310. The S/D isolation layer 113 has a portion horizontally aligned with the middle layer 107 along the x direction. The S/D isolation layer 113 is separated from the middle layer 107 by inner spacers 116. In an embodiment, the S/D isolation layer 113 has a thickness in the z direction greater than a thickness of the middle layer 107.

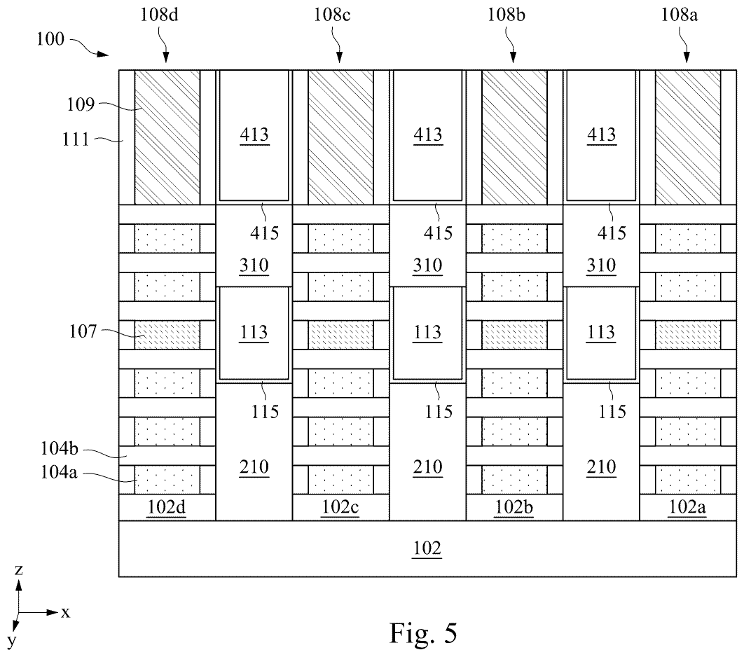

Now referring to FIG. 5, the method 1000 at operation 1014 epitaxially grows second S/D features 310 in the S/D trenches 519 and over the S/D isolation layer 113 for top transistor devices of the CFET device 100. The top transistor devices may be NFET transistor devices or PFET transistor devices. As such, the second source/drain features 310 may include n-type source/drain features that correspond with n-type transistor regions or p-type source/drain features that correspond with p-type transistor regions. The second source/drain features 310 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of semiconductor stacks 104 (in particular, semiconductor layers 104b). Epitaxial source/drain features are doped with n-type dopants and/or p-type dopants. In some embodiments, for the n-type CFET transistors, second epitaxial source/drain features 310 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In some embodiments, for the p-type CFET transistors, second epitaxial source/drain features 310 include silicon germanium or germanium and can be doped with boron, other p-type dopant, or combinations thereof (for example, forming Si:Ge:B epitaxial source/drain features). In the embodiment shown, the second S/D features 310 are n-type S/D features for NFET devices.

Still referring to FIG. 5, the second S/D features 310 may completely fill the S/D trenches 519 such that top surfaces of the second S/D features 310 are substantially coplanar with top surfaces of the topmost second semiconductor layers 104b. Alternatively, the second S/D features 310 may grow above the top surfaces of the topmost second semiconductor layers 104b. Note that the second S/D features 310 are in direct contact with semiconductor layers 104b for top transistor devices above the middle layer 107, but not the semiconductor layers 104b below the middle layer 107. Note that in some embodiments, like as shown, the second S/D features 310 need not be in direct contact with all the semiconductor layers 104b above the middle layer 107.

Still referring to FIG. 5, the method 1000 at operation 1016 forms an interlayer dielectric (ILD) layer 413 over the second S/D features 310. This may be done by first conformably depositing a dielectric liner such as an etch stop layer 415 by CVD, ALD or other suitable processes, then depositing the ILD layer 413 over the etch stop layer 415. A planarization process such as CMP may follow to planarize top surfaces of the ILD layer 413, etch stop layer 415, and dummy gate structures 110. The etch stop layer 415 may include silicon nitride and the ILD layer 413 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof.

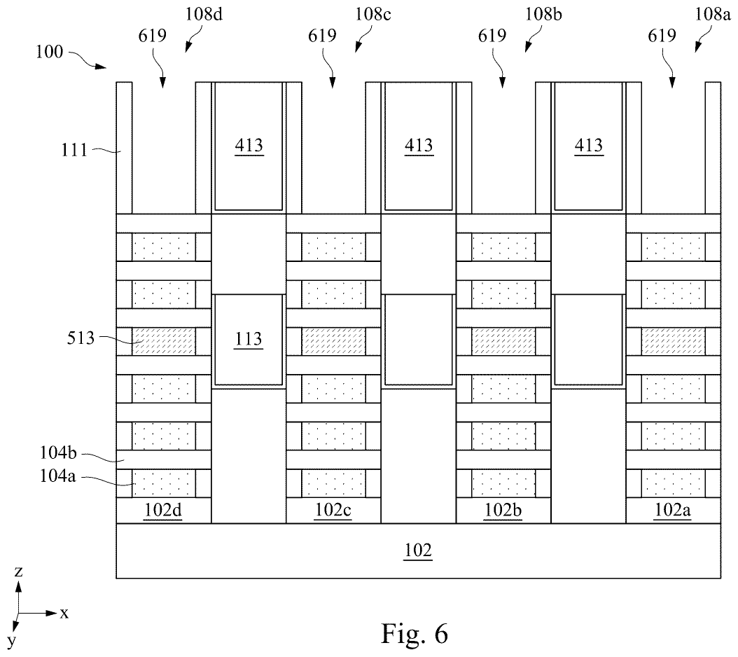

Now referring to FIG. 6, the method 1000 at operation 1018 removes dummy gate stacks 109 from the dummy gate structures 110. The dummy gate stacks 109 are removed by a suitable etching process, thereby resulting in gate trenches 619 and exposing the semiconductor stacks 104. The etching process is designed with an etchant to selectively remove the dummy gate stacks 109. In the depicted embodiment, an etching process completely removes dummy gate stacks 109 to expose surfaces of the semiconductor layers 104a and semiconductor layers 104b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 109, such as the dummy gate electrode layers, the dummy gate dielectric layers, and/or the hard mask layers. In some embodiments, the etching process is configured to selectively etch dummy gate stacks 109 with minimal (to no) etching of other features of the device 100, such as ILD layer 413, gate spacers 111, semiconductor layers 104a, and semiconductor layers 104b. In some embodiments, a lithography process is performed to form a patterned mask layer that covers the ILD layer 413 and/or gate spacers 111, and the etching process uses the patterned mask layer as an etch mask.

Still referring to FIG. 6, the method 1000 at operation 1020 removes the middle layer 107 and replaces it with a channel isolation layer 513. The middle layer 107 is removed by a suitable etching process. The etching process is designed with an etchant to selectively remove the middle layer 107. As described above, the middle layer 107 has a different concentration of materials such as heavier germanium concentration than other first semiconductor layers 104a (which also include germanium). This allows for selective etching of the middle layer 107 without etching the remaining semiconductor layers 104a. Thereafter, the air void that remains is filled with a dielectric material to form the channel isolation layer 513. The channel isolation layer 513 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the channel isolation layer 513 includes a low-k dielectric material. For example, the channel isolation layer 513 may include oxide derivatives such as fluorine-doped oxides, carbon-doped oxides, and/or hydrogen-doped oxides. For another example, the channel isolation layer 513 may include porous oxides such as xeorogels/aerogels. For another example, the channel isolation layer 513 may include organics such as polyimides, Teflon/PTFE, and/or other polymers. In some embodiments, the formation of the channel isolation layer 513 includes etching, deposition, and anisotropic etch, such as plasma etch.

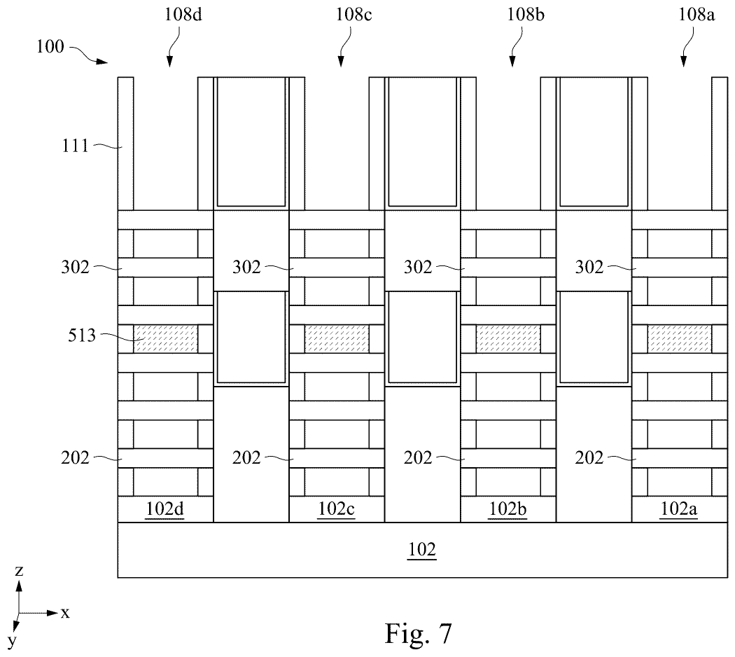

Now referring to FIG. 7, the method 1000 at operation 1022 forms suspended semiconductor channels 202/302 by removing the remaining first semiconductor layers 104a by a suitable etching process. The etching process is designed with an etchant to selectively remove the remaining first semiconductor layers 104a without substantially etching the second semiconductor layers 104b and the channel isolation layer 513. As such, the second semiconductor layers 104b become suspended semiconductor channels 202/302. The suspended semiconductor channels 202 refer to channel layers 202 for the bottom transistor devices (e.g., PFET channels of the CFET device 100) and the suspended semiconductor channels 302 refer to channel layers 302 for the top transistor devices (e.g., NFET channels of the CFET device 100).

With respect to selectively etching the middle layer 107 and selectively etching the first semiconductor layers 104a, various etching parameters can be tuned such as etchant composition, etching temperature, etching solution concentration, etching time, etching pressure, source power, RF bias voltage, RF bias power, etchant flow rate, other suitable etching parameters, or combinations thereof. For example, an etchant is selected to etch the material of the middle layer 107 (e.g., highest concentration of germanium) at a higher rate than the remaining semiconductor layers 104a (e.g., middle concentration of germanium). And an etchant is selected for the etching process that etches the semiconductor layers 104a (e.g., middle concentration of germanium) at a higher rate than the material of the semiconductor layers 104b (e.g., lowest concentration of germanium or no germanium). The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH₄OH) and water (H₂O) to selectively etch the germanium-containing semiconductor layers. In some embodiments, a chemical vapor phase etching process using hydrochloric acid (HCl) is used.

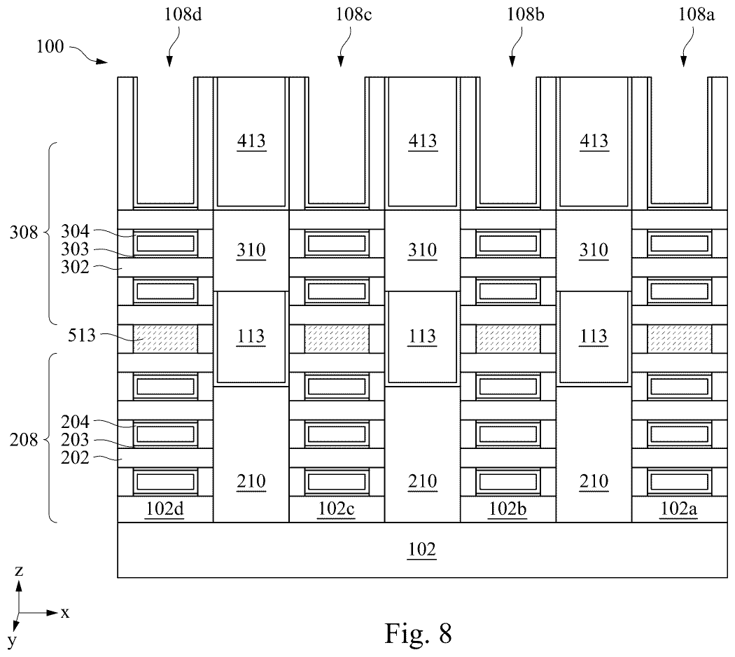

Now referring to FIG. 8, the method 1000 at operation 1024 forms gate dielectric layers 204/304 over the channel regions 102a-102d and wrapping around each of the suspended semiconductor channels 202/302. The gate dielectric layers 204/304 partially fills the gaps between the suspended semiconductor channels 202/302 and may include high-k dielectric materials such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba, Sr)TiO₃ (BST), Si₃N₄, hafnium dioxide-alumina (HfO₂—Al₂O₃) alloy, other suitable high-k dielectric material, or combinations thereof. The gate dielectric layers 204/304 may be formed by any of the processes described herein, such as ALD, CVD, PVD, oxidation-based deposition process, other suitable process, or combinations thereof. In an embodiment, before forming the gate dielectric layers 204/304, interfacial layers 203/303 are formed on the channel layers 202/302. The interfacial layers 203/303 may be formed by thermal oxidation, chemical oxidation, ALD, CVD, or other suitable processes. The interfacial layers 203/303 may include a dielectric material, such as SiO₂, HfSiO, SiON, other silicon-containing dielectric material, other suitable dielectric material, or combinations thereof.

Still referring to FIG. 8, the CFET gate regions 108 are divided into gate regions 208 below the channel isolation layer 513 and gate regions 308 above the channel isolation layer 513. For purposes of description, the gate regions 208 are described as PFET gate regions 208, and the gate regions 308 are described as NFET gate regions 308. As such, the NFET gate regions 308 are vertically above the PFET gate regions 208 such that NFET devices are formed over PFET devices. However, the present disclosure is not limited thereto. In other embodiments, the PFET gate regions 208 may be above the NFET gate regions 308 such that PFET devices are formed over NFET devices.

Still referring to FIG. 8, the PFET gate regions 208 include interfacial layers 203 directly on top and bottom surfaces of the channel layers 202. The PFET gate regions further include gate dielectric layers 204 directly on top and bottom surfaces of the interfacial layers 203 and on side surfaces of the inner spacers 116. The NFET gate regions 308 include interfacial layers 303 directly on top and bottom surfaces of the channel layers 302. The NFET gate regions 308 further include gate dielectric layers 304 directly on top and bottom surfaces of the interfacial layers 303 and on side surfaces of the inner spacers 116 (and/or the gate spacers 111).

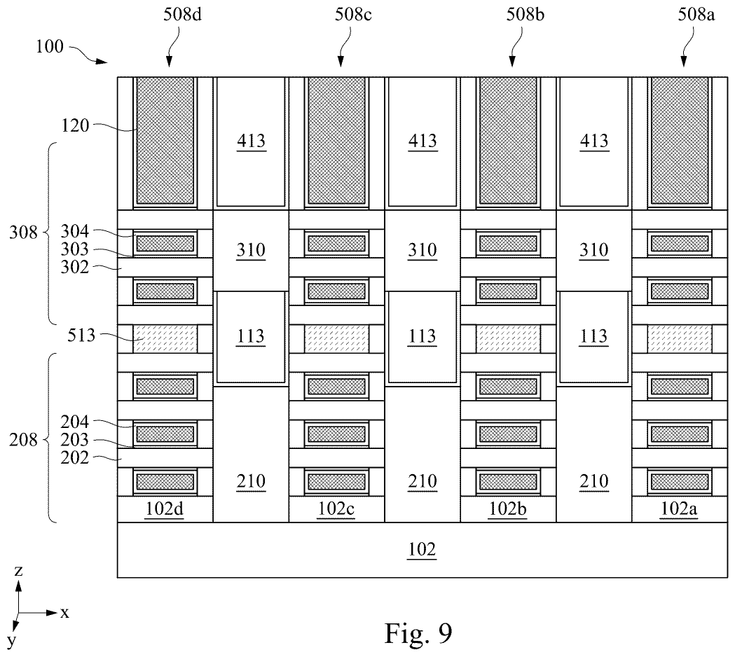

Now referring to FIG. 9, the method 1000 at operation 1026 deposits a gate metal 120 (also referred to as a metal gate electrode or a gate stack) over the first and second plurality of gate dielectric layers 204/304, thereby forming respective CFET metal gate structures 508a, 508b, 508c, and 508d. Note that gate metal 120 is not strictly defined as only containing metals; it may encompass a metal alloy, a cermet, or any suitable conductive materials. For example, the gate metal 120 may include Ti, Ag, Al, TiAl, TiAlN, TaC, TaCN, TaSiN, Mn, Zr, TiN, TaN, Ru, Mo, Al, WN, Cu, W, or any suitable materials. In the present embodiment, a gate metal 120 is deposited over both the PFET gate regions 208 and the NFET gate regions 308 (e.g., TiN). Then, the gate metal 120 is etched back or recessed to expose the NFET gate regions 308. Another gate metal 120 is then deposited over the exposed NFET gate regions 308 (e.g., Ti). This results in selective formation of different gate electrodes for a bottom device and a top device of the CFET device 100.

The gate metal 120 may include a capping layer, a work function metal layer, and a filling metal layer. The capping layer may include titanium nitride, tantalum nitride, or other suitable material, formed by a proper deposition technique such as ALD. The filling metal layer may include aluminum, copper, silicide, suitable other metal, or metal alloy deposited physical vapor deposition (PVD) or other suitable deposition technology.

The work function metal layer includes a conductive layer of metal or metal alloy with proper work function such that the corresponding FET is enhanced for its device performance. The work function (WF) metal layer is different for a PFET and an NFET, respectively referred to as an n-type WF metal and a p-type WF metal. The choice of the WF metal depends on the FET to be formed on the active region. For example, an n-type WF metal is a metal having a first work function such that the threshold voltage of the associated NFET is reduced. For example, the n-type WF metal has a work function of about 4.2 eV or less. A p-type WF metal is a metal having a second work function such that the threshold voltage of the associated PFET is reduced. For example, the p-type work function metal has a WF of about 5.2 eV or higher. An n-type WF metal may comprise a metal with sufficiently low effective work function such as titanium, aluminum, tantalum carbide, tantalum carbide nitride, tantalum silicon nitride, or combinations thereof. A p-type WF metal may comprise a metal with a sufficiently large effective work function, such as titanium nitride, tantalum nitride, ruthenium, molybdenum, tungsten, platinum, or combinations thereof.

In some embodiments, instead of, or in addition to using work function metals to tune the respective n-type and p-type FETs, the filling metal themselves are n- and p-type specific. For example, a p-type gate metal 120 (which may include p-type work function or fill metals) is deposited over the PFET gate regions 208. The p-type gate metal 120 wraps around channels 202. After gate etch-back, an n-type gate metal 120 (which may include n-type work function or fill metals) is then deposited over the NFET gate regions 308. The n-type gate metal 120 wraps around channels 302. Note that in cases where the PFET and NFET gate regions 208 and 308 are flipped, respective p-type and n-type gate metals 120 are also flipped accordingly.

Additional operations can be provided before, during, and after method 1000, and some of the operations described can be moved, replaced, or eliminated for additional embodiments of method 1000. Additional operations may include forming device-level contacts connecting to S/D features 210/310 and/or the metal gates of the CFET metal gate structure 508a-508d. Additional operations may further include forming interconnect structures over the device-level contacts. The interconnect structures may include one or more interconnect layers with wires and vias embedded in dielectric layers. The one or more interconnect layers connecting gate, source, and drain electrodes of various transistors, as well as other circuits in the device 100, to form an integrated circuit in part or in whole. Additional operations may further include forming passivation layer(s) over the interconnect layers.

In a stacked semiconductor device (e.g., a CFET device 100), forming a dual-tiered gate (one for a top device and one for a bottom device) requires a metal gate-etch back process to prepare for deposition of the top metal gate electrode. The metal gate-etch back may cause damage to exposed top gate dielectric layers (e.g., gate dielectric layers 304 for the top device). This and other issues are addressed by the methods described herein below.

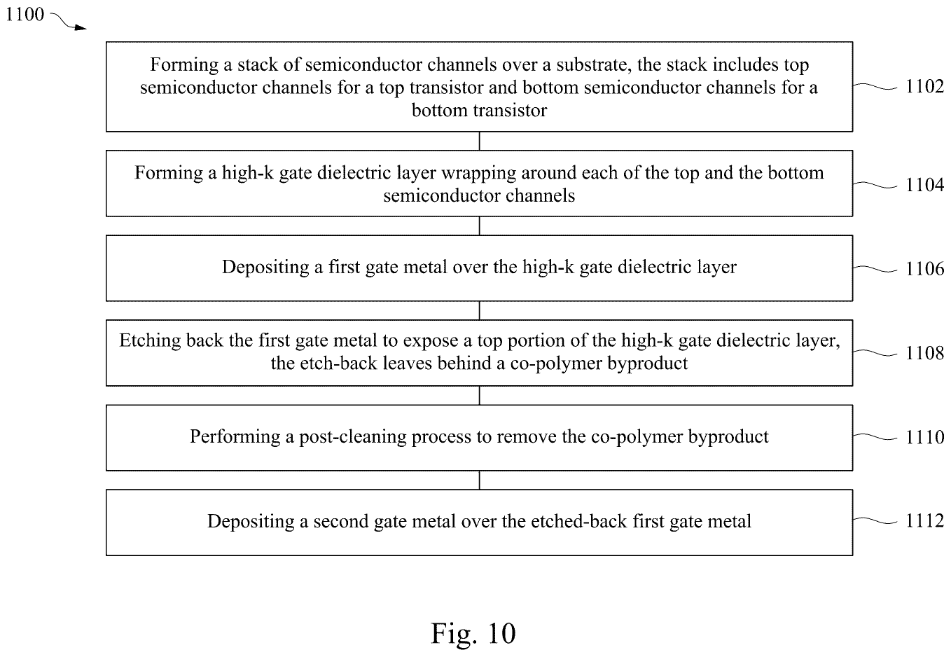

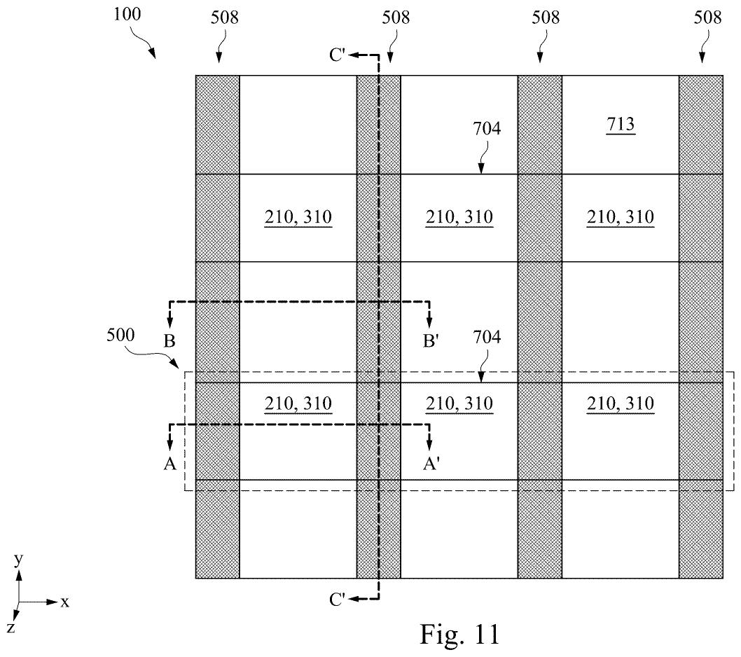

FIG. 10 illustrates a flow chart of a method 1100 for metal gate etch-back in a stacked semiconductor device (e.g., a CFET device 100), in portion or in entirety, according to an embodiment of the present disclosure. In an embodiment, the semiconductor device 100 at the end (or towards the end) of method 1000 is received at the beginning of method 1100, and the received semiconductor device 100 continues to be processed according to the method 1100. The method 1100 is described below with reference to FIGS. 11, 12A-12C, 13A-13C, 14A-14C, and 15A-15C. These figures have been simplified for the sake of clarity to better understand the inventive concepts of the present disclosure. Additional features can be added in the semiconductor device 100, and some of the features described below can be replaced, modified, or eliminated in other embodiments of the semiconductor device 100.

FIG. 11 illustrates a top view of a semiconductor workpiece after the method 1000 of FIGS. 1A-1B and with lines A-A′, B-B′, and C-C′ cut across the workpiece. The workpiece corresponds to the semiconductor device 100 at the end of method 1000 (e.g., at the stage illustrated in FIG. 9) or at some fabrication stage after the method 1000. The workpiece includes a region 500 corresponding to the regions shown and described in FIGS. 2-9. As shown in FIG. 11, the semiconductor device 100 may include other regions as part of a larger semiconductor structure making up an IC circuit. In the embodiment shown, the semiconductor device 100 includes two active regions 704 extending lengthwise along the x direction. Each of the active region 704 may correspond to a semiconductor stack 104 previously processed and described. The semiconductor device 100 includes four CFET metal gate structures 508 (e.g., CFET metal gate structures 508a-508d) extending lengthwise along the y direction. The CFET metal gate structures 508 extends across channel regions of the active regions 704 and wraps around respective semiconductor channels 202 and 302 in the channel regions. Each active regions 704 includes first and second S/D features 210 and 310 adjacent the channel regions. In the embodiment shown, each of the metal gate structures 508 extends across two active regions 704. Laterally between the active regions and laterally between the CFET metal gate structures 508 is an ILD structure 713 that may include one or more ILD layers (e.g., S/D isolation layer 113 and ILD layer 413) and one or more etch stop layers (e.g., etch stop layers 115 and 415).

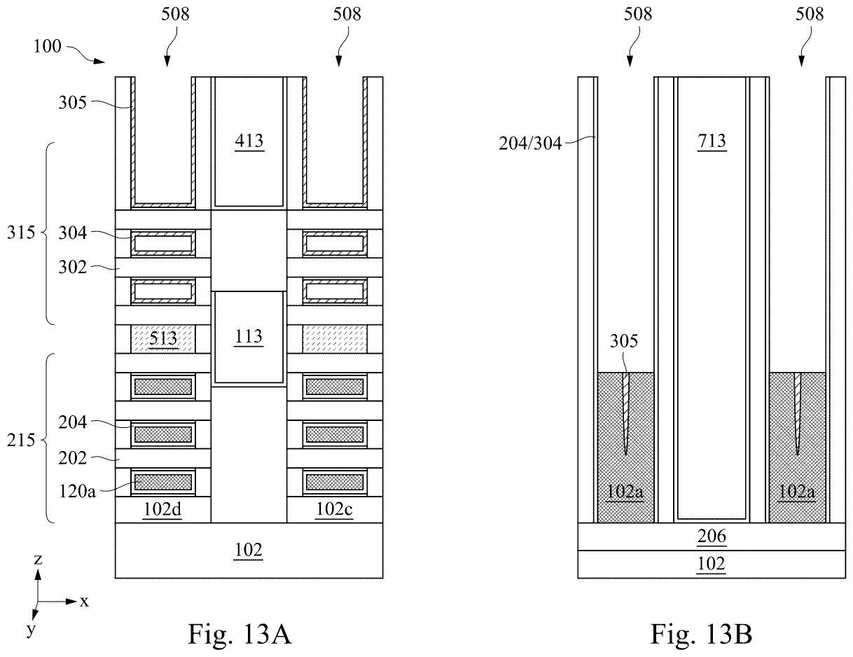

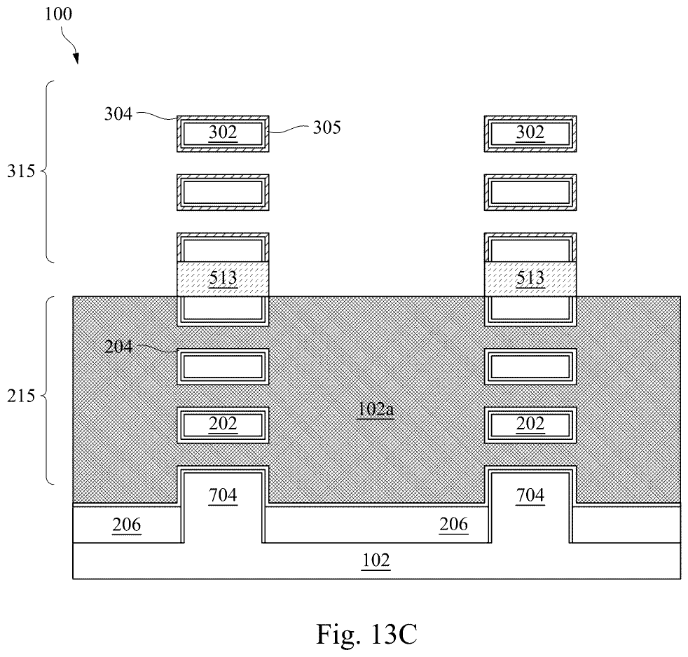

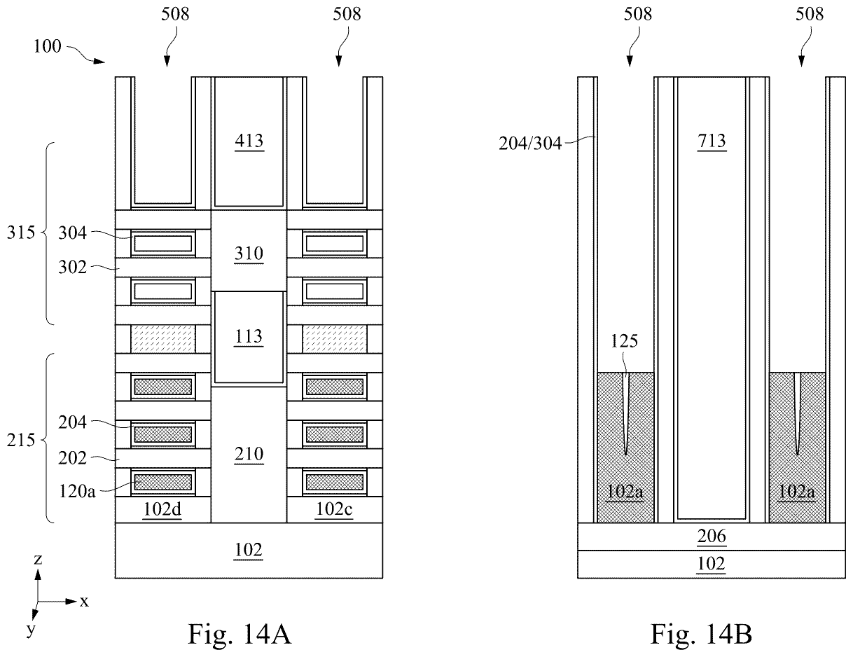

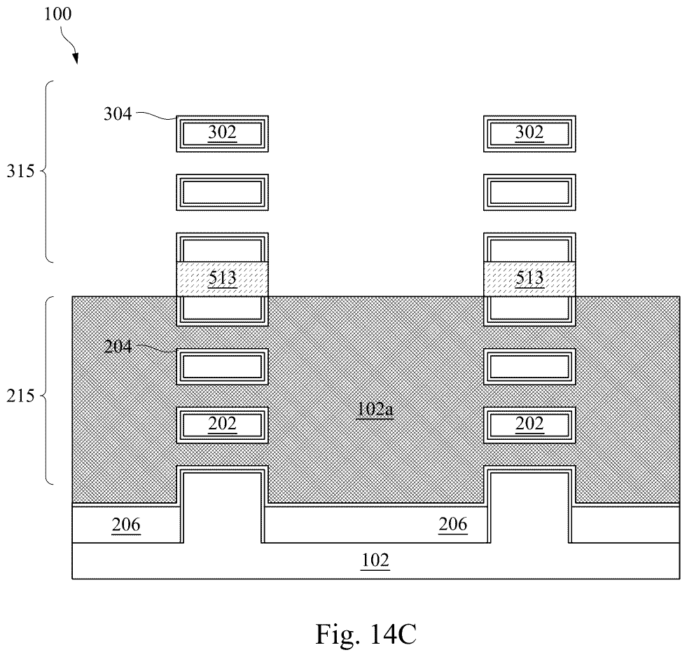

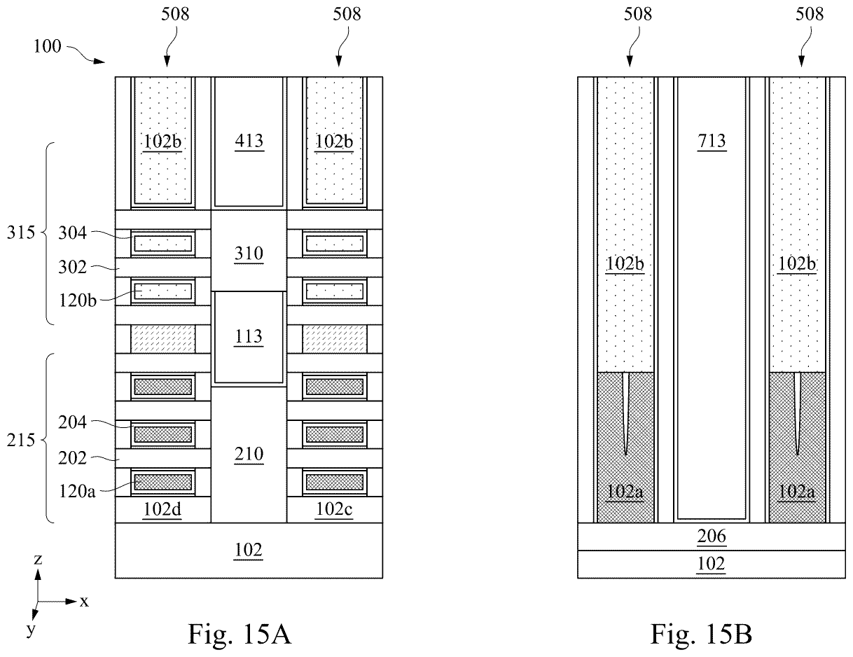

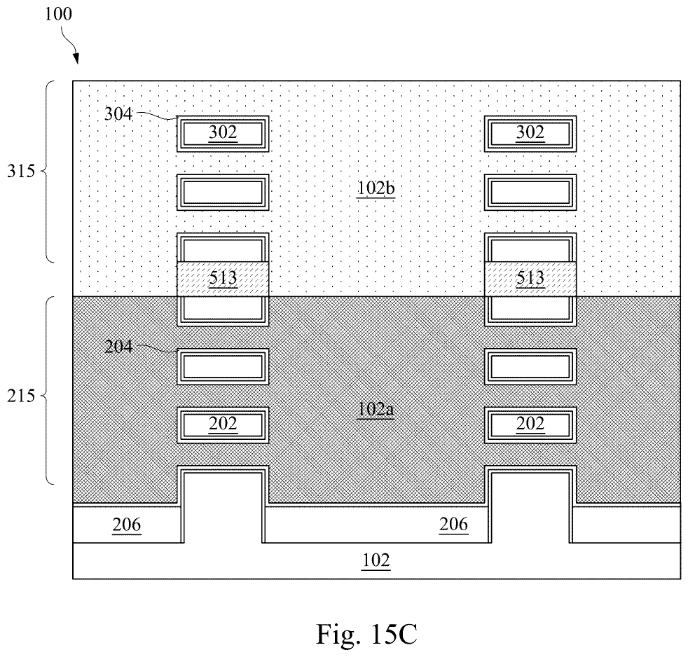

Still referring to FIG. 11, the line A-A′ cuts lengthwise in the x direction along an active region 704 and across two metal gate structures 508. The line B-B′ cuts lengthwise in the x direction parallel to the line A-A′ and across an isolation structure between active regions 704. The isolation structure may be a shallow trench isolation (STI) structure 206 as shown in FIGS. 12B and 12C. The line C-C′ cuts lengthwise in the y direction along a metal gate structure 508 and across channel regions of two of the active regions 704. FIGS. 12A, 13A, 14A, and 15A illustrate cross-sectional views of the semiconductor device 100 cut along the line A-A′ at intermediate stages of fabrication and processed in accordance with the method 1100 of FIG. 10. FIGS. 12B, 13B, 14B, and 15B illustrate cross-sectional views of the semiconductor device 100 cut along the line B-B′ at intermediate stages of fabrication and processed in accordance with the method 1100 of FIG. 10. FIGS. 12C, 13C, 14C, and 15C illustrate cross-sectional views of the semiconductor device 100 cut along the line C-C′ at intermediate stages of fabrication and processed in accordance with the method 1100 of FIG. 10. FIGS. 12A-12C are at a same stage of fabrication, FIGS. 13A-13C are at a same stage of fabrication, FIGS. 14A-14C are at a same stage of fabrication, and FIGS. 15A-15C are at a same stage of fabrication.

For ease of understanding, some of the features described in FIGS. 2-9 are renamed when describing the method 1100 and its associated figures. This is to better describe various features in the context of top transistors disposed over bottom transistors. As now described below, bottom transistors of the semiconductor device 100 are referred to as including bottom semiconductor channels 202 wrapped around by bottom gate electrodes 120a with adjacent bottom S/D features 210. Whereas top transistors of the semiconductor device 100 are referred to as including top semiconductor channels 302 wrapped around by top gate electrodes 120b with adjacent top S/D features 310. The S/D isolation layer 113 is referred to as a bottom ILD (BILD) layer 113, and the ILD layer 413 is referred to as a top ILD (TILD) layer 413.

The method 1100 may include various operations described with respect to method 1000, thereby forming the structures shown in FIGS. 12A-12C. For example, various features illustrated in FIG. 12A have been previously described with respect to method 1000, and some of the features will not be described again for the sake of brevity.

Referring now to FIGS. 12A-12C collectively, the method 1100 at operation 1102 forms a stack of semiconductor channels over a substrate 102, the stack includes top semiconductor channels 302 for a top transistor 315 and bottom semiconductor channels 202 for a bottom transistor 215. The top transistor 315 and the bottom transistor 215 may be formed in or over an active region 704 described in FIG. 11. As shown in FIGS. 12A and 12C, the top and the bottom semiconductor channels 302 and 202 are separated by the channel isolation layer 513 previously described.

In the cross-sectional view of FIGS. 12B and 12C, an isolation structure such as a shallow trench isolation (STI) structure 206 is formed over the substrate 102. The STI structure 206 isolates adjacent active regions 704. As shown in FIG. 12C, the active regions 704 are formed over the substrate 102 to protrude above the STI structure 206. The STI structure 206 may include silicon oxide, silicon oxynitride, fluorine-doped silicate glass (FSG), a low-k dielectric, combinations thereof, and/or other suitable materials. In an embodiment, the STI structure 206 includes an oxide-based dielectric such as silicon oxide. Referring to FIG. 12B, the ILD structure 713 is formed over the STI structure 206 between two metal gate structures 508. In an embodiment, the ILD structure 713 may be formed at the same time as forming the BILD layer 113. The difference is that the ILD structure 713 is not recessed like the BILD layer 113 because it is not in the S/D regions. The ILD structure 713 may be formed by first conformably depositing a dielectric liner such as an etch stop layer 715 by CVD, ALD or other suitable processes between the metal gate structures 508 and over the STI structure 206, then depositing the ILD structure 713 over the etch stop layer 715. In an embodiment, the ILD structure 713 includes same or similar materials as the BILD layer 113, and the etch stop layer 715 includes same or similar materials as the etch stop layer 115. Note that in the cross-sectional view of FIGS. 12B, the gate spacers 111 continuously extends from a top surface of the metal gate structures 508 to a top surface of the STI structure 206.

Still referring to FIGS. 12A-12C, the method 1100 at operation 1104 forms a high-k gate dielectric layer wrapping around each of the top and the bottom semiconductor channels 302 and 202. The high-k gate dielectric layer includes a top portion for forming top gate dielectric layers 304 and a bottom portion for forming bottom gate dielectric layers 204. Note that in the cross-sectional view of FIG. 12B, the high-k gate dielectric layer (e.g., gate dielectric layers 204/304) also line sidewalls of the gate spacers 111. Operation 1104 may correspond to operation 1024 previously described.

Still referring to FIGS. 12A-12C, the method 1100 at operation 1106 deposits a first gate metal (shown as bottom gate electrodes 120a) over the high-k gate dielectric layer (e.g., gate dielectric layers 204/304). The first gate metal wraps around each of the top and the bottom semiconductor channels 302 and 202 and will be recessed in a later step to form bottom gate electrodes 120a. In an embodiment, the first gate metal includes titanium nitride (TiN). Due to high aspect ratio in regions above the STI structure 206, as shown in FIG. 12B, metal voids (or seams) 125 may be formed within the first gate metal. Although not shown, the metal voids 125 may also be present in other regions of the device 100. Operation 1106 may correspond to operation 1026 previously described.

Referring now to FIGS. 13A-13C collectively, the method 1100 at operation 1108 etches back the first gate metal (shown as bottom gate electrodes 120a) to expose a top portion of the high-k gate dielectric layer (e.g., shown as top gate dielectric layers 304), the etch-back leaves behind a co-polymer byproduct 305. The co-polymer byproduct 305 covers surfaces of the exposed top gate dielectric layers 304 and further plugs the metal voids 125. The etch-back intentionally generates the co-polymer byproduct 305 to act as a protection layer during the etch-back. Specifically, as the first gate metal is being etched back, the generated co-polymer byproduct 305 simultaneously covers and protects the exposed top gate dielectric layers 304 and the metal voids 125 from etchant damage.

The etch-back includes dry etching using radicals formed of (or formed from) Cl₂/SiCl₄/O₂ or Clₓ/SiₓCl_{y}/Oₓ/COₓ. In the present embodiment, the etch-back uses radical etching (instead of plasma etching). Radical etching uses neutral radicals for etching and is typically isotropic, relying on the chemical reactions between neural radicals and the surface atoms of the material being etched. On the other hand, plasma etching typically uses charged ions within the plasma for directional etching. In this case, radical etching has advantages over plasma etching due to greater penetration for deeper etch-back. Further, the radical etching includes neutral radicals that is highly selective in etching metal and avoiding gate dielectric damage.

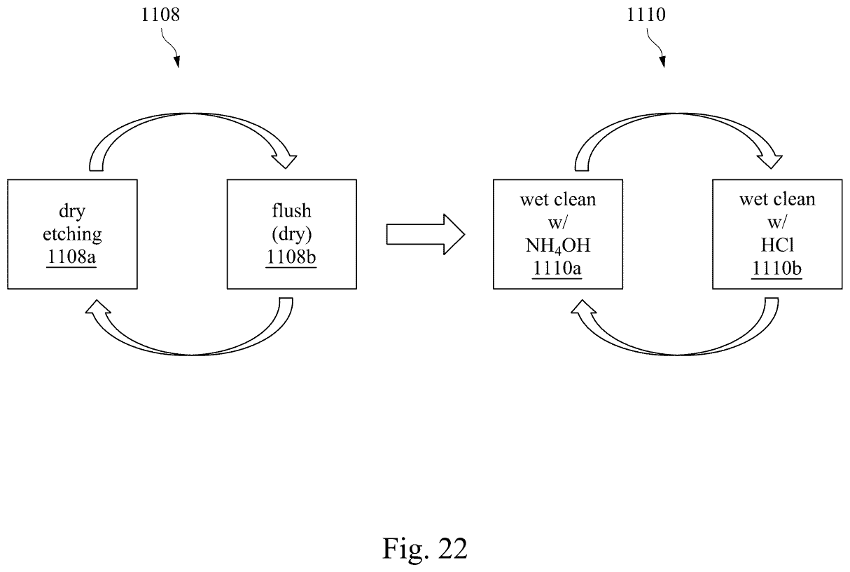

The co-polymer byproduct 305 is generated due (in part) to silicon components of the radicals. In the present embodiment, the co-polymer byproduct 305 is a heavy removable polymer comprising silicon and oxide (e.g., SiOₓ). To assist in the dry etching, the etch-back further includes a dry flush using chlorine gas (Cl₂) and/or methane gas (CH₄) to remove residue polymers on a top etched surface of the first gate metal. The dry etching and dry flush may be performed cyclically until the gate (e.g., metal gate structures 508) is etched-back to the desired height. As shown in FIG. 13C, the desired height may be just enough to still cover the bottom gate dielectric layers 204 (i.e., coplanar with a top surface of the topmost bottom semiconductor channel 202). However, the desired height may be anywhere between a top and a bottom surface of the channel isolation layer 513. As a result, the etched-back first gate metal forms bottom gate electrodes 120a for the bottom transistor(s) 215. Additional details of the etch-back operation 1108 is described with respect to FIG. 22.

Referring now to FIGS. 14A-14C collectively, the method 1100 at operation 1110 performs a post-cleaning process to remove the co-polymer byproduct 305. The post-cleaning process is a wet cleaning process. The post-cleaning process includes a first wet cleaning using a first wet solution to remove silicon oxide components of the co-polymer byproduct 305 and a second wet cleaning using a second wet solution to remove metal oxide components of the co-polymer byproduct 305. In the present embodiment, the first wet solution includes NH₄OH, and the second wet solution includes HCL. The post-cleaning process is a cyclic process that performs the first and the second wet cleaning recursively. In an embodiment where the first gate metal (i.e., bottom gate electrodes 120a) includes titanium, the wet cleaning process uses NH₄OH radicals to remove the SiO components from a SiₓTi_{y}O_{z} co-polymer by-product and HCL to remove the TiO components from the SiₓTi_{y}O_{z} co-polymer by-product. The two types of wet cleans complements each other to achieve complete removal of the co-polymer byproduct 305. As shown in FIG. 14B, the post-cleaning process also removes portions of the co-polymer byproduct 305 plugging the metal voids 125. Additional details of the post-clean operation 1108 is described with respect to FIGS. 22-24.

Referring now to FIGS. 15A-15C collectively, the method 1100 at operation 1112 deposits a second gate metal (shown as top gate electrodes 120b) over the etched-back first gate metal (shown as bottom gate electrodes 120a). In an embodiment, the second gate metal includes aluminum (Al). The second gate metal wraps around and is deposited over the exposed and cleaned top gate dielectric layers 304 for the top transistors 315. Thereafter, a planarization process such as CMP may be performed to planarize top surfaces of the second gate metal, the gate spacers 111, the ILD layer 413, and the ILD structure 713. As a result, the second gate metal forms top gate electrodes 120b for the top transistor(s) 315. In an embodiment, the top gate electrodes 120b include different materials from the bottom gate electrodes 120a. In an embodiment where top transistor(s) 315 are PFET(s) and the bottom transistor(s) 215 are NFET(s), the top gate electrodes 120b have a higher work function than the bottom gate electrodes 120a. In an embodiment where top transistor(s) 315 are NFET(s) and the bottom transistor(s) 215 are PFET(s), the top gate electrodes 120b have a lower work function than the bottom gate electrodes 120a. In the present embodiment, the top transistor 315 is an NFET and the bottom transistor is a PFET, where the top gate electrode 120b includes an n-type work function metal (e.g., aluminum) and the bottom gate electrode 120a includes a p-type work function metal (e.g., titanium nitride).

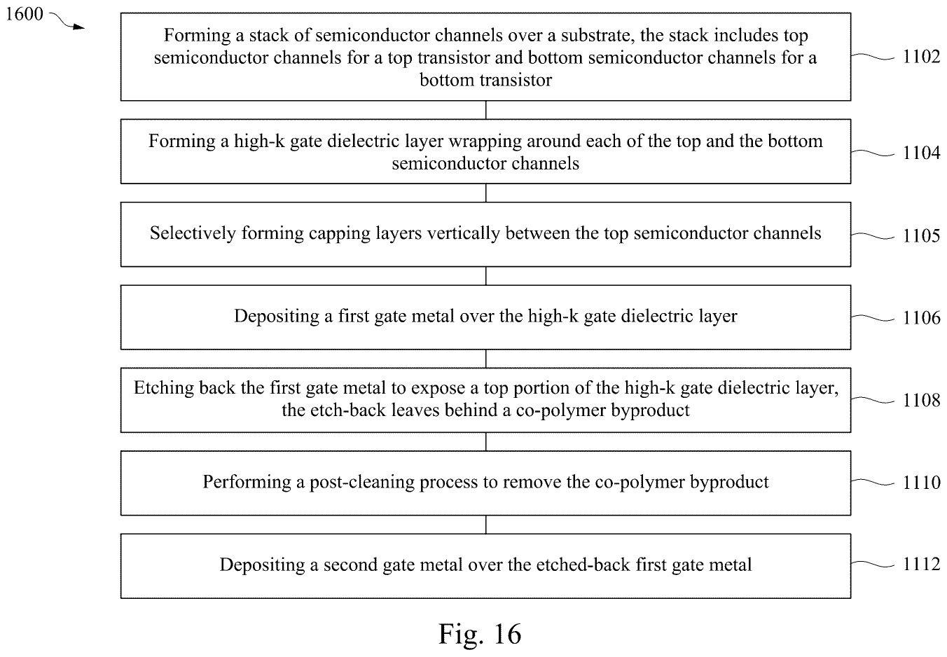

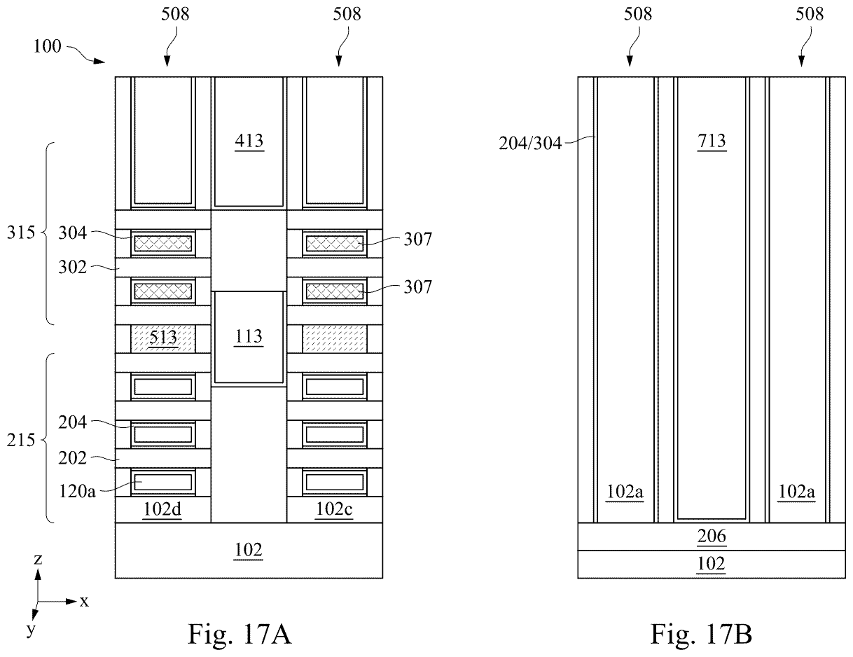

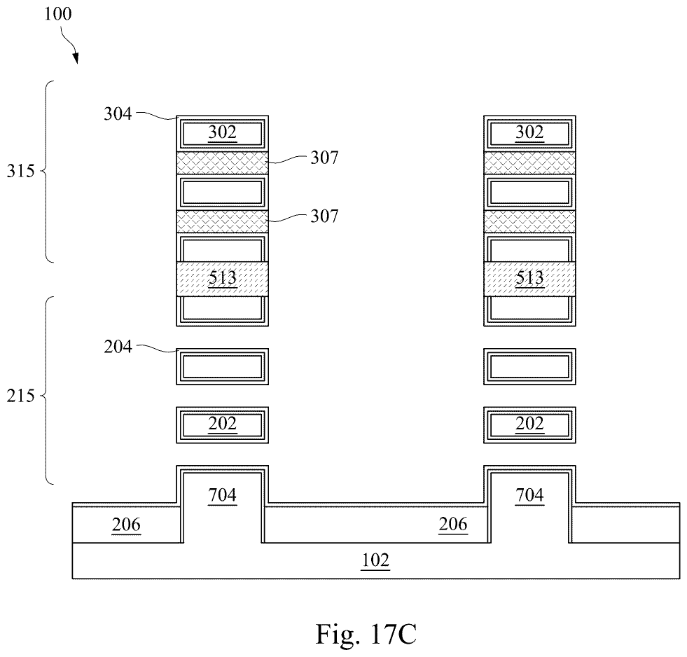

FIG. 16 illustrates a flow chart of a method 1600 for metal gate-etch back in a stacked semiconductor device (e.g., a CFET device 100), in portion or in entirety, according to another embodiment of the present disclosure. Method 1600 is similar to method 1100; therefore, some of similar features will not be described again for the sake of brevity. The difference in method 1600 is in the further inclusion of sacrificial capping layers 307. The sacrificial capping layers 307 provide further protection to the top dielectric layers 304 during the metal gate etch-back process. The sacrificial capping layers 307 are formed after the gate dielectric layers 202/302 are formed and before the first gate metal (e.g., bottom gate electrodes 120a) is deposited. In the present embodiment, the sacrificial capping layers 307 include aluminum oxide (AlOₓ). The method 1600 is described below with reference to FIGS. 17A-17C, 18A-18C, 19A-19C, 20A-20C, and 21A-21C. These figures have been simplified for the sake of clarity to better understand the inventive concepts of the present disclosure. Additional features can be added in the semiconductor device 100, and some of the features described below can be replaced, modified, or eliminated in other embodiments of the semiconductor device 100.

Referring to FIGS. 17A-17C collectively, the method 1600 at operation 1102 forms a stack of semiconductor channels over a substrate 102, the stack includes top semiconductor channels 302 for a top transistor 315 and bottom semiconductor channels 202 for a bottom transistor 215. The top and the bottom semiconductor channels 302 and 202 are separated by the channel isolation layer 513 previously described. The top transistor 315 and the bottom transistor 215 may be formed in or over an active region 704 described in FIG. 11. The operation 1102 has been previously described and will not be repeated again for the sake of brevity.

Still referring to FIGS. 17A-17C, the method 1600 at operation 1104 forms a high-k gate dielectric layer wrapping around each of the top and the bottom semiconductor channels 302 and 202. The high-k gate dielectric layer includes a top portion for forming top gate dielectric layers 304 and a bottom portion for forming bottom gate dielectric layers 204. The operation 1104 has been previously described and will not be repeated again for the sake of brevity.

Still referring to FIGS. 17A-17C, the method 1600 at operation 1105 selectively forms sacrificial capping layers 307 vertically between the top semiconductor channels 302. The sacrificial capping layers 307 are specifically designed to protect the high-k gate dielectric materials during the metal gate etch-back process. The sacrificial capping layers 307 may be formed by first depositing a capping layer over and wrapping around the high-k gate dielectric layer (i.e., the top and bottom gate dielectric layers 304/204). The capping layer completely fills the space vertically between both top and bottom semiconductor channels 302 and 202. Then, a selective etching process is performed to etch away excess portions of the capping layer (e.g., side and top portions) such that only portions of the capping layer disposed vertically between the semiconductor channels 302/202 remain. Then, another selective etching process is performed to remove portions of the capping layer vertically between the bottom semiconductor channels 202. In other words, the capping layer in the bottom transistor 215 (e.g., below the channel isolation layer 513) is selectively etched away such that the capping layer is only in the top transistor 315 (e.g., above the channel isolation layer 513). The remaining portions of the capping layer form the sacrificial capping layers 307. In the present embodiment, the capping layer includes aluminum oxide.

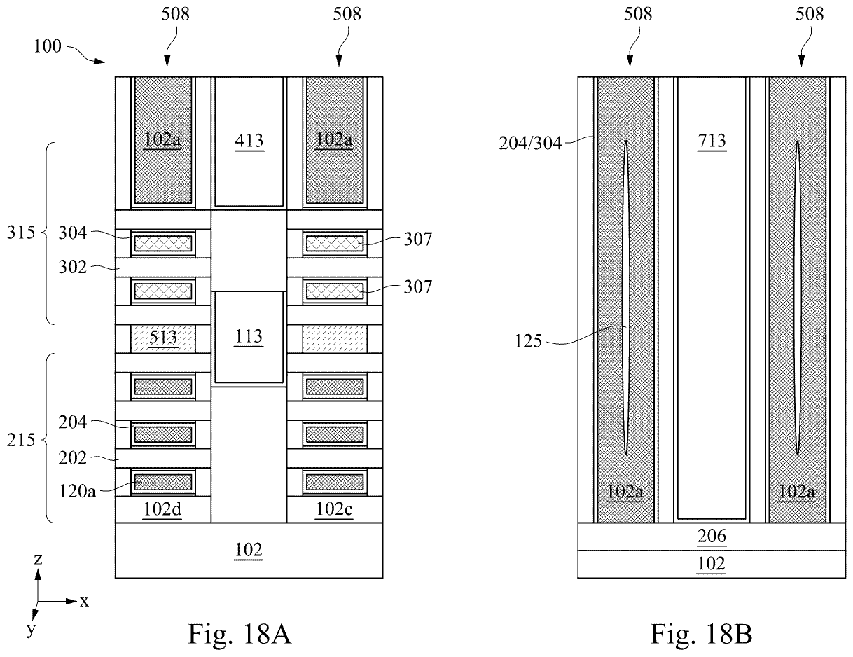

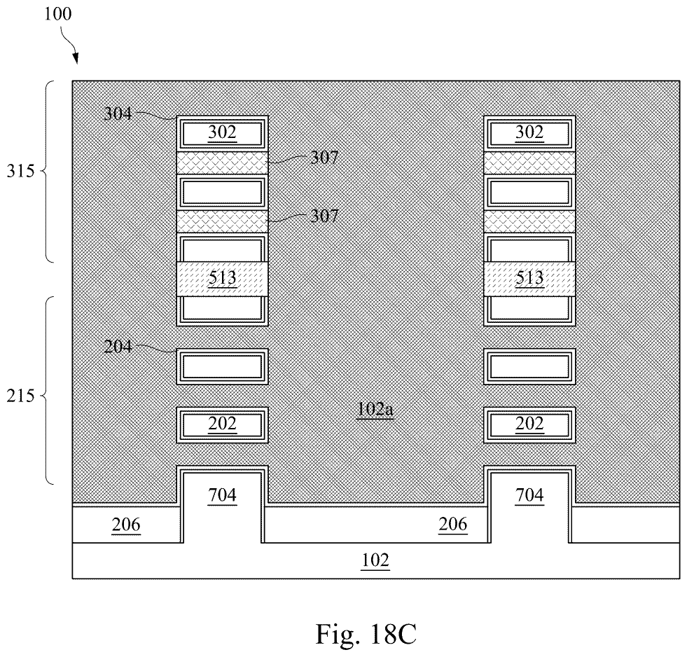

Referring now to FIGS. 18A-18C, the method 1600 at operation 1106 deposits a first gate metal (shown as bottom gate electrodes 120a) over the high-k gate dielectric layer (e.g., gate dielectric layers 204/304). Due to the presence of the sacrificial capping layers 307, the first gate metal vertically wraps around each of the bottom semiconductor channels 202 but not the top semiconductor channels 302. This is because the sacrificial capping layers 307 block the spaces vertically between the top semiconductor channels 302. As shown in FIG. 18C, the first gate metal (shown as bottom gate electrodes 120a) is formed vertically between the bottom semiconductor channels 202 and on sidewalls of the sacrificial capping layers 307. In other aspects, the operation 1106 with respect to FIGS. 18A-18C is similar to FIGS. 12A-12C.

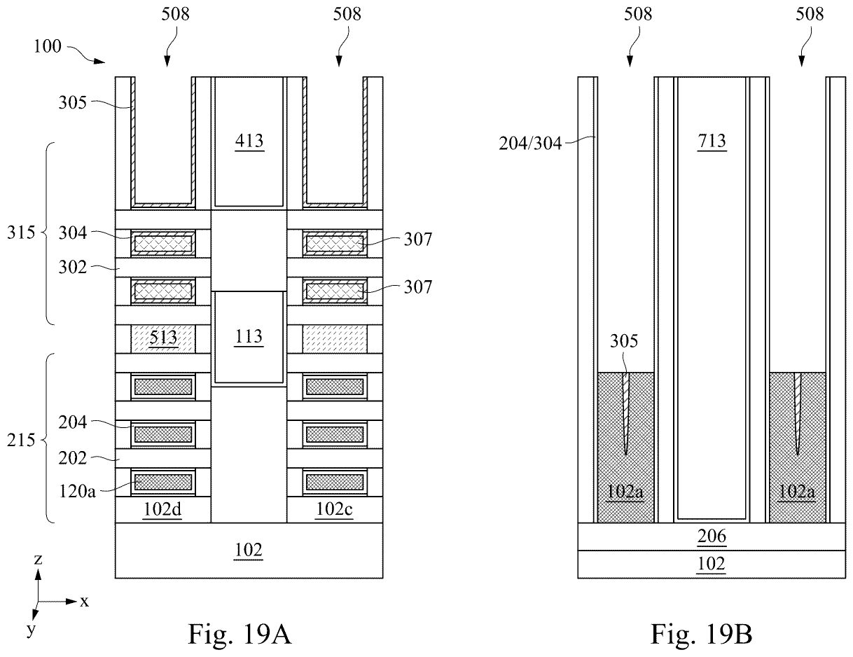

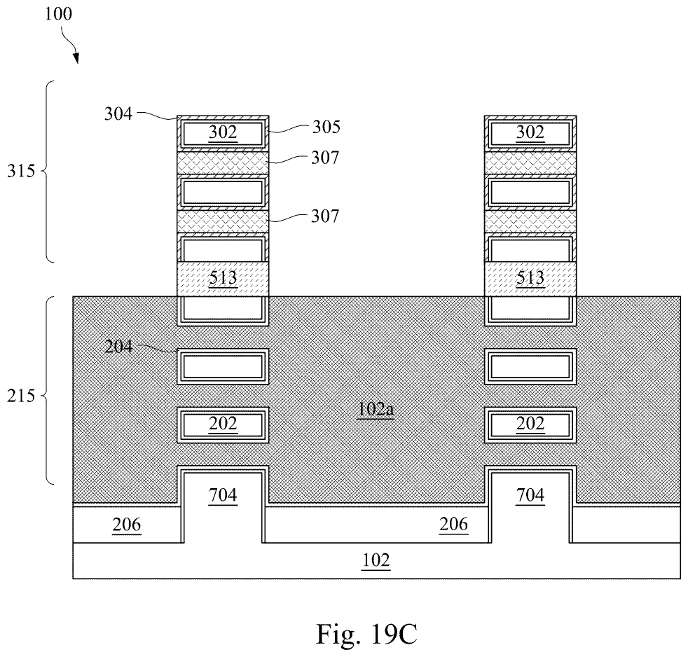

Referring now to FIGS. 19A-19C, the method 1600 at operation 1108 etches back the first gate metal (shown as bottom gate electrodes 120a) to expose a top portion of the high-k gate dielectric layer (e.g., shown as top gate dielectric layers 304). Like in method 1100, the etch-back leaves behind a co-polymer byproduct 305. Note that in this case, the first gate metal is etched back while the sacrificial capping layers 307 remain in place. Due to the presence of the sacrificial capping layers 307, there is additional etchant protection for the top gate dielectric layers 304. In both methods 1100 and 1600, the etchant used during operation 1108 is highly selective to etching the first gate metal and highly selective against etching the high-k gate dielectric layer (and other surrounding features). However, due to how thin the high-k gate dielectric layer is, there may still be risk of etchant damage. Therefore, the sacrificial capping layers 307 provide the extra buffer to avoid etchant damage. In other aspects, the operation 1108 with respect to FIGS. 19A-19C is similar to FIGS. 13A-13C.

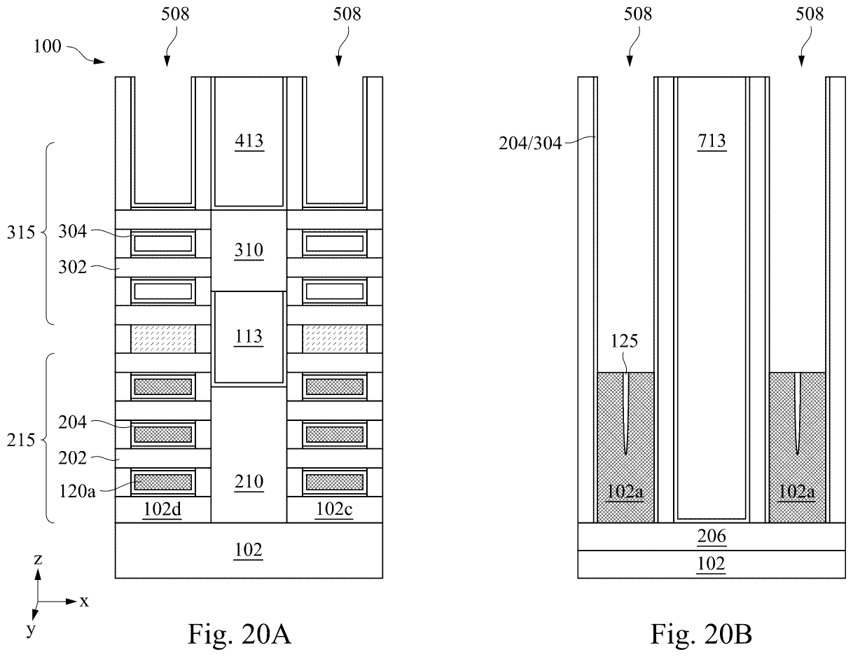

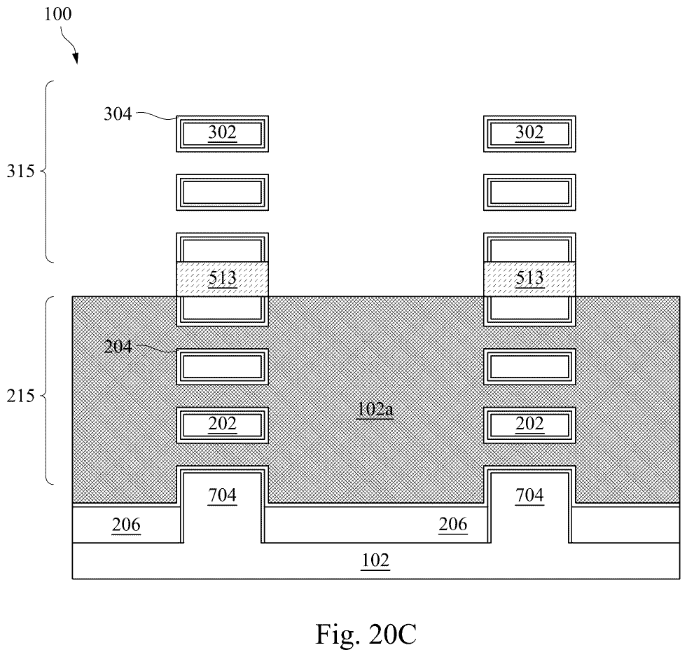

Referring now to FIGS. 20A-20C collectively, the method 1600 at operation 1110 performs a post-cleaning process to remove the co-polymer byproduct 305 and the sacrificial capping layers 307. The operation 1110 in method 1600 is similar to that of method 1100, except that the post-cleaning process further removes the sacrificial capping layers 307. In the present embodiment, the sacrificial capping layers 307 are first removed by a first removal process, then the co-polymer byproduct 305 are removed by a second removal process. The first removal process may be any suitable selective etching process targeting the sacrificial capping layers 307. The second removal process corresponds to the post-cleaning process described with respect to method 1100. During the first removal process, the co-polymer byproduct 305 protects the top gate dielectric layers 304 from etchant damage. In other aspects, the operation 1110 with respect to FIGS. 20A-20C is similar to FIGS. 14A-14C.

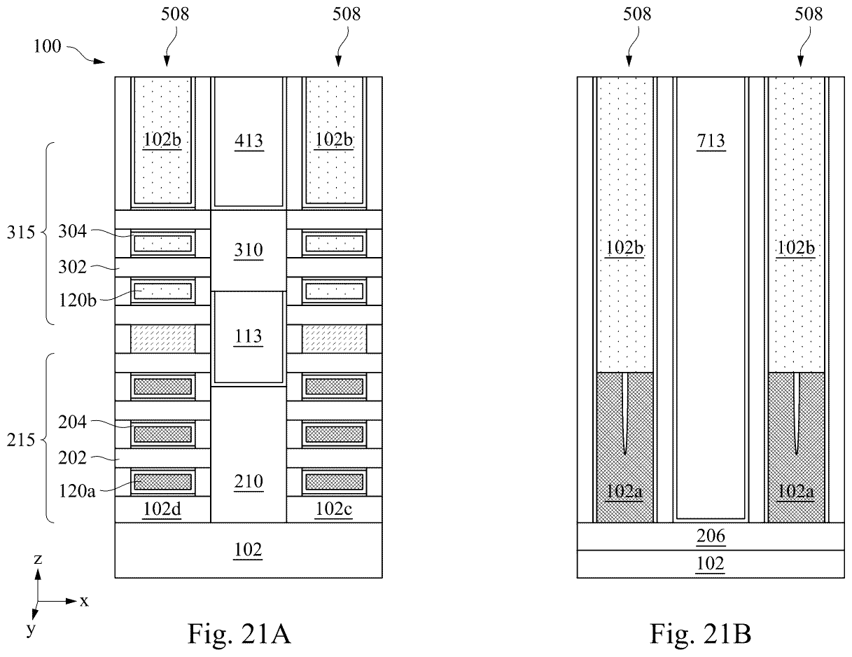

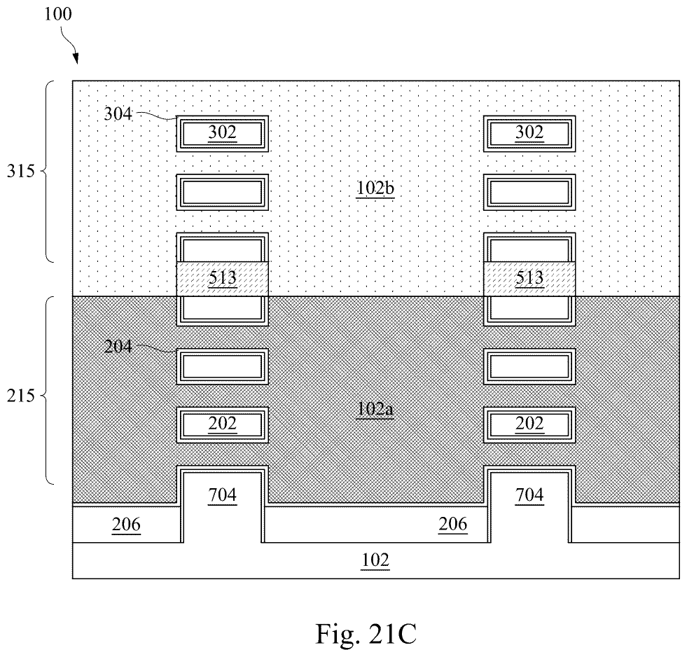

Referring now to FIGS. 21A-21C collectively, the method 1600 at operation 1112 deposits a second gate metal (shown as top gate electrodes 120b) over the etched-back first gate metal (shown as bottom gate electrodes 120a). The operation 1112 has been previously described and will not be repeated again for the sake of brevity.

FIG. 22 illustrates a manufacturing flow including an etch-back and a post-clean process, according to an embodiment of the present disclosure. The etch-back process corresponds to operation 1108 and includes dry etching 1108a and dry flush 1108b. The post-clean process corresponds to operation 1110 and includes a first wet clean 1110a using NH₄OH and a second wet clean 1110b using HCl. The etch-back has a first continuous cycle of dry etching 1108a and dry flush 1108b, and the post-clean has a second continuous cycle of first wet clean 1110a and second wet clean 1110b. Additional details of the etch-back and post-clean process are described below.

In the etch-back process (i.e., operation 1108), the dry etching 1108a applies plasma over the CFET device 100. The dry etching 1108a is configured to selectively etch the exposed first gate without substantially etching other features (e.g., gate spacers 111, ILD layers, etc.). This exposes the top gate dielectric layers 304 in the top transistor device 315. Various types of ion shielding may be used to filter out the ions in the plasma, leaving behind the neutral radicals for radical etching. The neural radicals forms a heavy polymer byproduct (e.g., co-polymer byproduct 305 containing SiO₂), which may be used to plug the metal voids 125 described herein and to protect and cover the top gate dielectric layers 304. The plasma radicals for etching penetrates (or passes) through the polymer byproduct to etch metal and avoid high-k dielectric and metal void damage. For example, the etched gate metal may be TiN. The TiN is etched by applying plasma having radicals Cl₂+SiCl₄+O₂. The result is TiCl₄+SiO₂+N₂+Cl₂, to be later cleaned by a post-clean process. Following the dry etching 1108a, the dry flush 1108b applies a different plasma over the CFET device 100, which selectively removes the generated polymer byproduct (e.g., co-polymer byproduct 305) on the top surface of the first gate metal. This allows subsequent cycle of dry etching 1108a with radical Cl₂/SiCl₄ to proceed effectively, ensuring continuity in the etching process. In some embodiment, the dry flush 1108b also partially removes the polymer byproduct (e.g., co-polymer byproduct 304) on the high-k dielectric to avoid excessive build-up. The dry flush 1108b may apply chlorine gas (Cl₂) and/or methane gas (CH₄). The Cl₂ in the dry etching 1108a focuses on metal etching and the Cl₂ in the dry flush 1108b focuses on Si—O bond dissociation. As shown and previously described, the etch-back process continues its first continuous cycle until a desired gate height is achieved for the bottom transistor 215.

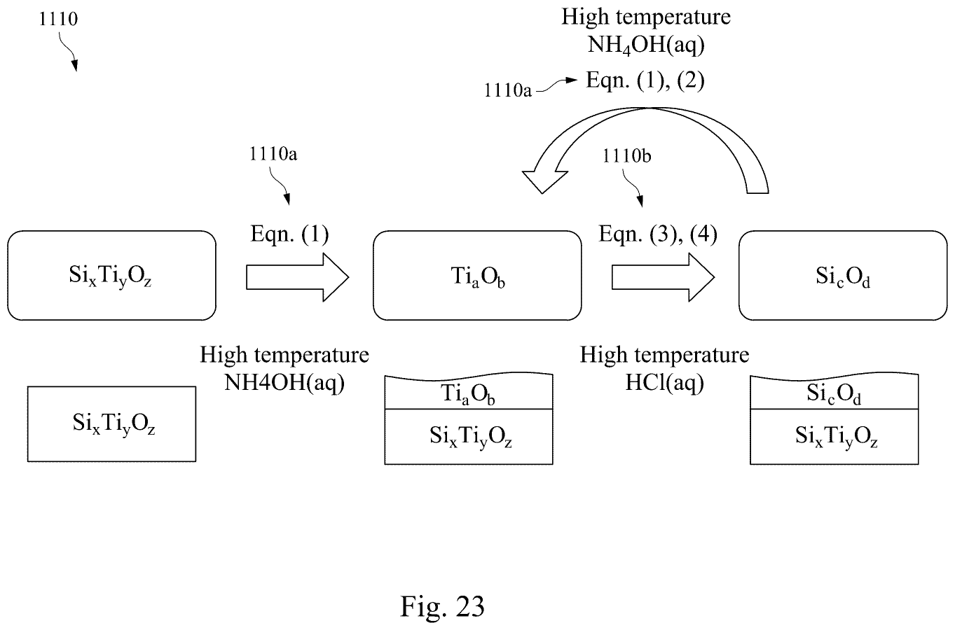

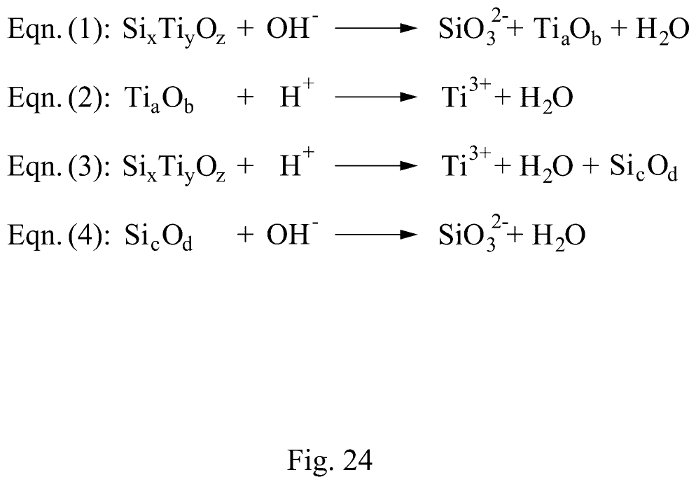

After the first continuous cycle of etch-back, a second continuous cycle of post-clean (i.e., operation 1110) begins. The post-clean process is a wet clean that uses NH₄OH to remove oxide containing by-products (i.e., first wet clean 1110a) and HCl to remove metal containing polymer (i.e., second wet clean 1110b). As a result, the entire generated polymer byproduct (e.g., co-polymer byproduct 305) is cleanly removed without high-k gate dielectric and metal damage, thereby maintaining stable threshold voltage and without device shift. Additional details of the post-clean (i.e., operation 1110) is described with respect to FIGS. 23-24.

FIG. 23 provides a flow diagram of the post-clean process (i.e., operation 1110). FIG. 24 provides the chemical formulas involved in the post-clean process. First, after dry etching the metal gate to a desired etch-back depth (e.g., operation 1108), SiₓTi_{y}O_{z} by-products remain (e.g., co-polymer byproduct 305). Thereafter, a cyclic wet clean at temperatures between 40 to 80 degrees Celsius is performed. If the temperature is too low (e.g., lower than about 40 degrees Celsius), residues of respective targeted materials may not be completely removed; while if the temperature is too high (e.g., greater than about 80 degrees), any benefit may be outweighed by the processing costs. The cyclic process separately removes SiOx and TiOx through applying NH₄OH and HCL, respectively. In an embodiment, a first wet clean 1110a includes NH₄OH cleaning—the NH₄OH reacts with the SixTiyOz co-polymer to selectively remove SiO components according to equations 1 and 2 of FIG. 24, leaving behind TiO components of the SiₓTi_{y}O_{z} by-products. In an embodiment, a second wet clean 1110b includes HCL cleaning—the HCL reacts with the remaining TiO components, selectively removing it according to equations 3 and 4 of FIG. 24, leaving behind the SiO components of the SiₓTi_{y}O_{z} by-products, where the cyclic cleaning cycle begins again. In other words, the cleaning in the first wet clean 1110a reveals TiO components, which is cleaned by step 2. The cleaning in the second wet clean 1110b reveals SiO components, which is cleaned again by the first wet clean 1110a and revealing more TiO components, and so on and so forth. In this way, each of the first and the second wet cleans 1110a and 1110b prepares the proper cleaning surfaces for the subsequent repeating steps. The cyclic cleaning cycle ends when the SixTiyOz co-polymer is completely broken down and removed. The first wet clean 1110a and second wet clean 1110b may be tuned separately and have varied cycle time and concentration for targeted cleaning. By separately targeting silicon oxide and metal oxide components, the SixTiyOz co-polymer is more easily broken down for complete removal. Further, by removing the co-polymer layer by layer in a cyclic process, damage to the underlying high-k gate dielectric is avoided.

Although titanium nitride (TiN) has been described as the gate material being etched, the present disclosure is not limited thereto. The present disclosure also applies to gate materials made of other metal or conductive materials. In any case, whatever metal or conductive materials are used, the etch-back process (i.e., operation 1108) selectively etches the gate metal and intentionally generates silicon oxide polymer byproducts to protect exposed high-k gate dielectric layers and metal voids. And the post-clean process (i.e., operation 1110) has separate wet cleaning processes to separately and cyclically remove the metal oxide components and the silicon oxide components of the polymer byproducts.

Although not limiting, the present disclosure offers advantages for metal gate etch-back. One example advantage is performing the metal gate etch-back with high selectivity between high-k gate dielectric and metal, preventing damage to the high-k gate dielectric. Another example advantage is intentionally generating heavy silicon oxide co-polymer byproducts to protect exposed high-k gate dielectric and metal voids from etching damage. Another example advantage is selecting plasma radicals that passes through the heavy silicon oxide-copolymers to only target etching the gate metal. Another example advantage is selective and complete removal of the co-polymer byproducts through cyclic wet clean and without damaging the high-k gate dielectric.

One aspect of the present disclosure pertains to a method. The method includes forming top semiconductor channels for a top device over bottom semiconductor channels for a bottom device; forming a high-k gate dielectric layer wrapping around each of the top and the bottom semiconductor channels; forming a first gate metal over the high-k gate dielectric layer; etching back the first gate metal to expose top portions of the high-k gate dielectric layer while bottom portions of the high-k gate dielectric layer remain, wherein the etching back includes dry etching to etch the first gate metal and to generate a co-polymer byproduct that covers the exposed top portions of the high-k gate dielectric layer; and performing a post-cleaning process to remove the co-polymer byproduct, the post-cleaning process comprising a first wet cleaning using a first wet solution to remove silicon oxide components of the co-polymer byproduct and a second wet cleaning using a second wet solution to remove metal oxide components of the co-polymer byproduct.

In an embodiment, the dry etching includes applying Cl₂/SiCl₄ radicals. In an embodiment, the first gate metal includes one or more metal seams, and the generated co-polymer byproduct plugs into the metal seams. In an embodiment, the first gate metal includes Ti, and the co-polymer byproduct includes SixTiyOz. In an embodiment, the post-cleaning process is a cyclic process that performs the first and the second wet cleaning recursively.

In an embodiment, the etching back further includes performing a dry flush using chlorine gas and methane gas to remove residue polymers on a top etched surface of the first gate metal. In a further embodiment, the dry etching and the dry flush are performed cyclically until the first gate metal is etched back to a desired height.

In an embodiment, after the post-cleaning process, the method includes forming a second gate metal over the etched back first gate metal.

In an embodiment, before the forming of the first gate metal, the method includes selectively forming capping layers vertically between the top semiconductor channels, wherein the first gate metal is formed vertically between the bottom semiconductor channels and on sidewalls of the capping layers; etching back the first gate metal while the capping layers remain in place; and removing the capping layers after the etching back. In an embodiment, the capping layers include aluminum oxide.

Another aspect of the present disclosure pertains to a method. The method includes forming top semiconductor channels for a top device over bottom semiconductor channels for a bottom device; forming a high-k gate dielectric layer wrapping around each of the top and the bottom semiconductor channels; forming a first gate metal over the high-k gate dielectric layer; etching back the first gate metal to expose top portions of the high-k gate dielectric layer while bottom portions of the high-k gate dielectric layer remain, wherein the etching back leaves behind a co-polymer byproduct that covers the exposed top portions of the high-k gate dielectric layer and plugs into one or more metal voids in the first gate metal, wherein the co-polymer byproduct includes silicon oxide; performing a post-cleaning process to remove the co-polymer byproduct; and forming a second gate metal over the etched back first gate metal, wherein the etched back first gate metal forms a first gate electrode for the bottom device and the second gate metal forms a second gate electrode for the top device.

In an embodiment, the etching back includes performing a dry etching and a dry flush cyclically, the dry etching selectively etches the first gate metal without etching the co-polymer byproduct, and the co-polymer byproduct protects the high-k gate dielectric layer and the metal voids from being etched. In an embodiment, the dry flush removes residue polymers on a top etched surface of the first gate metal using chlorine gas, methane gas, or a combination thereof.

In an embodiment, the post-cleaning process includes a first wet cleaning using a first wet solution to remove silicon oxide components of the co-polymer byproduct and a second wet cleaning using a second wet solution to remove metal oxide components of the co-polymer byproduct. In an embodiment, the first wet solution includes NH₄OH, and the second wet solution includes HCL. In an embodiment, the post-cleaning process is a cyclic process that performs the first and the second wet cleaning recursively.

Another aspect of the present disclosure pertains to a method. The method includes forming top semiconductor channels for a top device over bottom semiconductor channels for a bottom device; forming a high-k gate dielectric layer wrapping around each of the top and the bottom semiconductor channels; forming a first gate metal over the high-k gate dielectric layer; etching back the first gate metal to expose top portions of the high-k gate dielectric layer while bottom portions of the high-k gate dielectric layer remain, wherein the etching back includes dry etching to etch the first gate metal and to generate a co-polymer byproduct that covers the exposed top portions of the high-k gate dielectric layer, wherein the dry etching generates radicals that penetrate through the co-polymer byproduct to etch the first gate metal; performing a post-cleaning process to remove the co-polymer byproduct, the post-cleaning process comprising a first wet cleaning using a first wet solution to remove first components of the co-polymer byproduct and a second wet cleaning using a second wet solution to remove second components of the co-polymer byproduct; and forming a second gate metal over the etched back first gate metal.

In an embodiment, the radicals of the dry etching includes Cl₂, SiCl4, O2, or combinations thereof, the co-polymer byproduct includes silicon and oxygen, and the first wet solution includes NH₄OH, and the second wet solution includes HCL.

In an embodiment, the etching back further includes performing a dry flush using chlorine gas or methane gas to remove residue polymers on a top etched surface of the first gate metal.

In an embodiment, the post-cleaning process is performed at a cyclic temperature between 40 degrees Celsius to 80 degrees Celsius.

The details of the method and system of the present disclosure are described in the attached drawings. The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
forming top semiconductor channels for a top device over bottom semiconductor channels for a bottom device;
forming a high-k gate dielectric layer wrapping around each of the top and the bottom semiconductor channels;
forming a first gate metal over the high-k gate dielectric layer;
etching back the first gate metal to expose top portions of the high-k gate dielectric layer while bottom portions of the high-k gate dielectric layer remain, wherein the etching back includes dry etching to etch the first gate metal and to generate a co-polymer byproduct that covers the exposed top portions of the high-k gate dielectric layer; and
performing a post-cleaning process to remove the co-polymer byproduct, the post-cleaning process comprising a first wet cleaning using a first wet solution to remove silicon oxide components of the co-polymer byproduct and a second wet cleaning using a second wet solution to remove metal oxide components of the co-polymer byproduct.

2. The method of claim 1, wherein the dry etching includes applying Cl₂/SiCl₄ radicals.

3. The method of claim 1, wherein the first gate metal includes one or more metal seams, and the generated co-polymer byproduct plugs into the metal seams.

4. The method of claim 1, wherein the first gate metal includes Ti, and the co-polymer byproduct includes SiₓTi_{y}O_{z}.

5. The method of claim 1, wherein the post-cleaning process is a cyclic process that performs the first and the second wet cleaning recursively.

6. The method of claim 1, wherein the etching back further includes performing a dry flush using chlorine gas and methane gas to remove residue polymers on a top etched surface of the first gate metal.

7. The method of claim 6, wherein the dry etching and the dry flush are performed cyclically until the first gate metal is etched back to a desired height.

8. The method of claim 1, further comprising:
after the post-cleaning process, forming a second gate metal over the etched back first gate metal.

9. The method of claim 1, further comprising:
before the forming of the first gate metal, selectively forming capping layers vertically between the top semiconductor channels, wherein the first gate metal is formed vertically between the bottom semiconductor channels and on sidewalls of the capping layers;
etching back the first gate metal while the capping layers remain in place; and
removing the capping layers after the etching back.

10. The method of claim 9, wherein the capping layers include aluminum oxide.

11. A method, comprising:
forming top semiconductor channels for a top device over bottom semiconductor channels for a bottom device;
forming a high-k gate dielectric layer wrapping around each of the top and the bottom semiconductor channels;
forming a first gate metal over the high-k gate dielectric layer;
etching back the first gate metal to expose top portions of the high-k gate dielectric layer while bottom portions of the high-k gate dielectric layer remain, wherein the etching back leaves behind a co-polymer byproduct that covers the exposed top portions of the high-k gate dielectric layer and plugs into one or more metal voids in the first gate metal, wherein the co-polymer byproduct includes silicon oxide;
performing a post-cleaning process to remove the co-polymer byproduct; and
forming a second gate metal over the etched back first gate metal,
wherein the etched back first gate metal forms a first gate electrode for the bottom device and the second gate metal forms a second gate electrode for the top device.

12. The method of claim 11, wherein the etching back includes performing a dry etching and a dry flush cyclically, the dry etching selectively etches the first gate metal without etching the co-polymer byproduct, and the co-polymer byproduct protects the high-k gate dielectric layer and the metal voids from being etched.

13. The method of claim 12, wherein the dry flush removes residue polymers on a top etched surface of the first gate metal using chlorine gas, methane gas, or a combination thereof.

14. The method of claim 11, wherein the post-cleaning process includes a first wet cleaning using a first wet solution to remove silicon oxide components of the co-polymer byproduct and a second wet cleaning using a second wet solution to remove metal oxide components of the co-polymer byproduct.

15. The method of claim 14, wherein the first wet solution includes NH₄OH, and the second wet solution includes HCL.

16. The method of claim 14, wherein the post-cleaning process is a cyclic process that performs the first and the second wet cleaning recursively.

17. A method, comprising:
forming top semiconductor channels for a top device over bottom semiconductor channels for a bottom device;
forming a high-k gate dielectric layer wrapping around each of the top and the bottom semiconductor channels;
forming a first gate metal over the high-k gate dielectric layer;
etching back the first gate metal to expose top portions of the high-k gate dielectric layer while bottom portions of the high-k gate dielectric layer remain, wherein the etching back includes dry etching to etch the first gate metal and to generate a co-polymer byproduct that covers the exposed top portions of the high-k gate dielectric layer, wherein the dry etching generates radicals that penetrate through the co-polymer byproduct to etch the first gate metal;
performing a post-cleaning process to remove the co-polymer byproduct, the post-cleaning process comprising a first wet cleaning using a first wet solution to remove first components of the co-polymer byproduct and a second wet cleaning using a second wet solution to remove second components of the co-polymer byproduct; and
forming a second gate metal over the etched back first gate metal.

18. The method of claim 17,
wherein the radicals of the dry etching includes Cl₂, SiCl₄, O₂, or combinations thereof,
wherein the co-polymer byproduct includes silicon and oxygen,
wherein the first wet solution includes NH₄OH, and the second wet solution includes HCL.

19. The method of claim 17, wherein the etching back further includes performing a dry flush using chlorine gas or methane gas to remove residue polymers on a top etched surface of the first gate metal.

20. The method of claim 17, wherein the post-cleaning process is performed at a cyclic temperature between 40 degrees Celsius to 80 degrees Celsius.
